(19) United States
(12) Patent Application Publication
(10) Pub. No.: US 2024/0004291 A1
(43) Pub. Date: Jan. 4, 2024

(54) COMPOSITION, TRANSFER FILM, MANUFACTURING METHOD OF LAMINATE, CURED FILM, AND DEVICE

(71) Applicant: FUJIFILM Corporation, Tokyo (JP)

(72) Inventors: Yohei ARITOSHI, Kanagawa (JP); Keigo YAMAGUCHI, Kanagawa (JP)

(73) Assignee: FUJIFILM Corporation, Tokyo (JP)

(21) Appl. No.: 18/467,898

(22) Filed: Sep. 15, 2023

(30) Foreign Application Priority Data
Mar. 2, 2022 (JP) 2022-158872

(51) Int. Cl. G03F 7/033; G03F 7/038; C08F 230/08

(52) U.S. Cl. CPC G03F 7/033; G03F 7/038; C08F 230/08

(57) ABSTRACT

Provided are a composition containing a binder polymer, a polymerizable compound, a polymer (X), and a solvent, in which the polymer (X) includes predetermined constitutional units, a transfer film, a manufacturing method of a laminate, a cured film, and a device.

### CROSS-REFERENCE TO RELATED APPLICATIONS

This application claims priority from Japanese Patent Application No. 2022-158872, filed Sep. 30, 2022, the entire disclosure of which is incorporated herein by reference.

### BACKGROUND OF THE INVENTION

### 1. Field of the Invention

The present disclosure relates to a composition, a transfer film, a manufacturing method of a laminate, a cured film, and a device.

### 2. Description of the Related Art

A photosensitive composition is used to form a resin pattern by photolithography.

For example, JP2014-041183A discloses “photosensitive resin composition containing a resin, a polymerizable compound, a polymerization initiator, and a compound represented by Formula (1), in which the resin is a resin including a copolymer which has a structural unit derived from at least one selected from the group consisting of an unsaturated carboxylic acid and an unsaturated carboxylic acid anhydride and has a structural unit derived from a monomer having a cyclic ether structure having 2 to 4 carbon atoms and an ethylenically unsaturated bond, the polymerization initiator is a polymerization initiator including an O-acyl oxime compound, and a content of the compound represented by Formula (1) is 0.25 parts by mass or more and 3 parts by mass or less with respect to 100 parts by mass of the resin”.

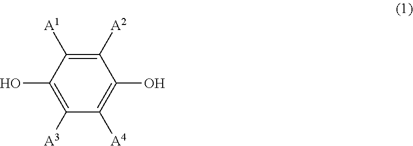

In Formula (1), A¹ to A⁴ each independently represent a hydrogen atom or an alkyl group having 1 to 6 carbon atoms.

### SUMMARY OF THE INVENTION

The photosensitive composition may be applied in a layered manner, and cured to form a cured film. The cured film is used for pattern formation. From the viewpoint of improving accuracy of the pattern formation, the cured film for pattern formation preferably has less thickness unevenness and less film defects.

An object to be achieved by one embodiment of the present disclosure is to provide a composition with which a cured film with less thickness unevenness and less film defects is obtained.

An object to be achieved by another embodiment of the present disclosure is to provide a transfer film with which a cured film with less thickness unevenness and less film defects is obtained.

An object to be achieved by another embodiment of the present disclosure is to provide a manufacturing method of a laminate including a cured film with less thickness unevenness and less film defects.

An object to be achieved by another embodiment of the present disclosure is to provide a cured film with less thickness unevenness and less film defects.

An object to be achieved by another embodiment of the present disclosure is to provide a device including a cured film with less thickness unevenness and less film defects. The methods for achieving the above-described objects include the following methods.

<1> A composition comprising:
a binder polymer;
a polymerizable compound;
a polymer (X); and
a solvent,
in which the polymer (X) includes a constitutional unit α represented by General Formula (A-1) or General Formula (A-2), and a constitutional unit β represented by General Formula (B).

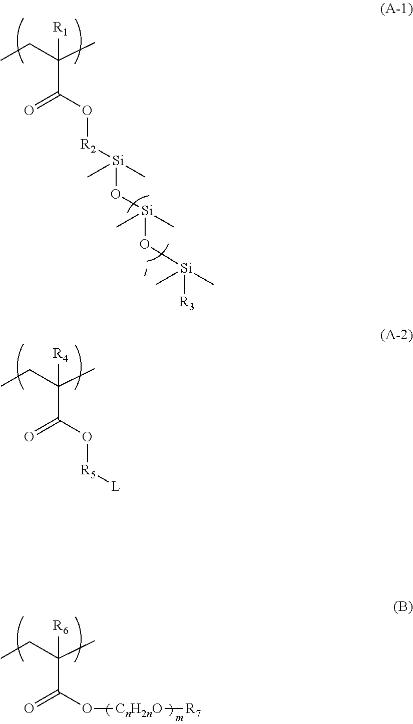

In General Formula (A-1), R₁ represents a hydrogen atom or a methyl group, R₂ represents an alkylene group having 1 to 10 carbon atoms, R₃ represents an alkyl group having 1 to 4 carbon atoms, and l represents an integer of 5 to 100.

In General Formula (A-2), R₄ represents a hydrogen atom or a methyl group, R₅ represents an alkylene group having 1 to 10 carbon atoms, and L represents a trimethylsilyl group or a tris(trimethylsiloxy)silyl group.

In General Formula (B), R₆ represents a hydrogen atom or a methyl group, R₇ represents a hydrogen atom or an alkyl group having 1 to 18 carbon atoms, m represents an integer of 1 to 100, and n represents an integer of 1 to 4.

<2> The composition according to <1>,
in which a mass ratio of the constitutional unit a and the constitutional unit β is 5:95 to 95:5.

<3> The composition according to <1> or <2>,
in which the polymer (X) includes a polymer (X-1) including the constitutional unit represented by General Formula (A-1) and the constitutional unit represented by General Formula (B), and a polymer (X-2) including the constitutional unit represented by General Formula (A-2) and the constitutional unit represented by General Formula (B).

<4> The composition according to <3>,
in which a mass ratio of the polymer (X-1) and the polymer (X-2) is 5:95 to 95:5.

<5> The composition according to <4>,
in which the mass ratio of the polymer (X-1) and the polymer (X-2) is 10:90 to 50:50.

<6> The composition according to any one of <1> to <5>,
in which a content of the polymer (X) with respect to a total mass of the composition is more than 0.05% by mass and less than 1.5% by mass.

<7> The composition according to any one of <1> to <6>,
in which, in General Formula (A-1), l is an integer of 5 to 50.

<8> A transfer film comprising, in the following order:
a temporary support; and
a photosensitive composition layer,
in which the photosensitive composition layer is a layer formed of the composition according to any one of <1> to <7>.

<9> A manufacturing method of a laminate, comprising:
a bonding step of bringing a surface of the transfer film according to <8> opposite to the temporary support into contact with a substrate having a conductive layer to bond the transfer film to the substrate, to obtain a photosensitive composition layer-attached substrate including the substrate, the conductive layer, the photosensitive composition layer, and the temporary support in this order;
an exposing step of exposing the photosensitive composition layer in a patterned manner; and
a developing step of developing the exposed photosensitive composition layer to form a protective film pattern which protects the conductive layer,
in which a peeling step of peeling off the temporary support from the photosensitive composition layer-attached substrate is provided between the bonding step and the exposing step or between the exposing step and the developing step.

<10> A cured film obtained by curing at least a part of the photosensitive composition layer in the transfer film according to <8>.

<11> A device comprising:
the cured film according to <10>.

According to one embodiment of the present disclosure, there is provided a composition with which a cured film with less thickness unevenness and less film defects is obtained.

According to another embodiment of the present disclosure, there is provided a transfer film with which a cured film with less thickness unevenness and less film defects is obtained.

According to another embodiment of the present disclosure, there is provided a manufacturing method of a laminate including a cured film with less thickness unevenness and less film defects.

According to another embodiment of the present disclosure, there is provided a cured film with less thickness unevenness and less film defects.

According to another embodiment of the present disclosure, there is provided a device including a cured film with less thickness unevenness and less film defects.

### BRIEF DESCRIPTION OF THE DRAWINGS

FIG. 1 is a schematic partial cross-sectional view showing an example of a layer configuration of a transfer film according to the embodiment of the present disclosure.

### DESCRIPTION OF THE PREFERRED EMBODIMENTS

Hereinafter, an embodiment which is an example of the present disclosure will be described. These descriptions and examples are only illustrative of the embodiments and do not limit the scope of the invention.

In numerical ranges described in stages in the present specification, an upper limit value or a lower limit value described in one numerical range may be replaced with an upper limit value or a lower limit value of a numerical range described in another stage. In addition, in the numerical ranges described in the present specification, the upper limit value or the lower limit value of the numerical ranges may be replaced with the values shown in examples. Each component may contain a plurality of kinds of substances corresponding thereto.

In a case where the amount of each component in a composition is referred to, and in a case where a plurality of substances corresponding to each component in the composition are present, it means the total amount of a plurality of substances present in the composition, unless otherwise specified.

“Step” includes not only an independent step but also a step that cannot be clearly distinguished from other steps, as long as the desired action of the step is achieved.

In the present specification, the numerical ranges shown using “to” indicate ranges including the numerical values described before and after “to” as the lower limit value and the upper limit value.

In the present specification, unless otherwise specified, a weight-average molecular weight (Mw) and a number-average molecular weight (Mn) are values obtained by a gel permeation chromatography (GPC) analysis apparatus and converted using polystyrene as a standard substance, with TSKgel GMHxL, TSKgel G4000HxL, or TSKgel G2000HxL (all product names manufactured by Tosoh Corporation) as a column, tetrahydrofuran (THF) as an eluent, a differential refractometer as a detector, and polystyrene as a standard substance.

Composition

The composition according to the present embodiment contains a binder polymer, a polymerizable compound, a polymer (X), and a solvent, in which the polymer (X) includes a constitutional unit a represented by General Formula (A-1) described above or General Formula (A-2) described above, and a constitutional unit β represented by General Formula (B) described above.

With the composition according to the present embodiment, due to the above-described configuration, a cured film with less thickness unevenness and less film defects is obtained. The reason is presumed as follows.

In the composition containing a binder polymer, a polymerizable compound, a polymer (X), and a solvent, since the polymer (X) includes a constitutional unit a represented by General Formula (A-1) described above or General Formula (A-2) described above, and a constitutional unit β represented by General Formula (B) described above, a thickness of a coating film obtained by applying the composition tends to be uniform, and air bubbles are less likely to be included in the coating film. Therefore, thickness unevenness and film defects of a cured film obtained by curing the coating film are suppressed.

Binder Polymer

The composition according to the embodiment of the present disclosure contains a binder polymer.

Examples of the binder polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the binder polymer include a (meth)acrylic resin.

In the present specification, the (meth)acrylic resin means a resin having a constitutional unit derived from a (meth)acrylic compound.

The content of the constitutional unit derived from a (meth)acrylic compound is preferably 50% by mass or more, more preferably 70% by mass or more, and still more preferably 90% by mass or more with respect to all constitutional units of the (meth)acrylic resin.

The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass or less with respect to all constitutional units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

Examples of the (meth)acrylamide include acrylamides such as diacetone acrylamide.

An alkyl group of the (meth)acrylic acid alkyl ester may be linear or branched. Specific examples thereof include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid ester, (meth)acrylic acid alkyl ester having an alkyl group having 1 to 4 carbon atoms is preferable, and methyl (meth)acrylate or ethyl (meth)acrylate is more preferable.

The (meth)acrylic resin may have a constitutional unit other than the constitutional unit derived from a (meth)acrylic compound.

The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an α-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid.

These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group.

Among these, the (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more and 50% by mass or less, and more preferably 10% by mass or more and 40% by mass or less with respect to the total mass of the (meth)acrylic resin.

In addition, it is more preferable that the (meth)acrylic resin has a constitutional unit derived from the above-described (meth)acrylic acid alkyl ester.

In a case of having a constitutional unit derived from the (meth)acrylic acid alkyl ester, a content of the constitutional unit derived from (meth)acrylic acid alkyl ester in the (meth)acrylic resin is preferably 1% by mass to 90% by mass, more preferably 1% by mass to 50% by mass, and still more preferably 1% by mass to 30% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable.

In addition, as the (meth)acrylic resin, an acrylic resin which has a constitutional unit derived from methacrylic acid, a constitutional unit derived from methyl methacrylate, and a constitutional unit derived from ethyl acrylate is also preferable.

In addition, the (meth)acrylic resin preferably has at least one selected from the group consisting of a constitutional unit derived from methacrylic acid and a constitutional unit derived from methacrylic acid alkyl ester, and more preferably has both the constitutional unit derived from methacrylic acid and the constitutional unit derived from methacrylic acid alkyl ester.

The total content of the constitutional unit derived from methacrylic acid and the constitutional unit derived from methacrylic acid alkyl ester in the (meth)acrylic resin is preferably 40% by mass or more and 100% by mass or less, and more preferably 60% by mass or more and 80% by mass or less with respect to all constitutional units of the (meth)acrylic resin.

In addition, examples of other suitable aspects of the binder polymer include an alkali-soluble resin.

From the viewpoint of developability, for example, the binder polymer is preferably a binder polymer having an acid value of 60 mgKOH/g or more.

In addition, from the viewpoint that it is easy to form a strong film by thermally crosslinking with a crosslinking component by heating, for example, the binder polymer is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group.

In a case where the binder polymer is a resin having a carboxy group, for example, the three-dimensional crosslinking density can be increased by adding a thermal crosslinking compound such as a blocked isocyanate compound and thermally crosslinking. In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected.

For example, a carboxy group-containing acrylic resin having an acid value of 60 mgKOH/g or more among polymers described in paragraph of JP2011-095716A, a carboxy group-containing acrylic resin having an acid value of 60 mgKOH/g or more among polymers described in paragraphs to of JP2010-237589A, and the like can be preferably used.

The binder polymer preferably has an aromatic ring structure, and more preferably has a constitutional unit having an aromatic ring structure.

Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable.

Examples of the aralkyl group include a substituted or unsubstituted phenylalkyl group (excluding a benzyl group), and a substituted or unsubstituted benzyl group, and a substituted or unsubstituted benzyl group is preferable.

In addition, the binder polymer more preferably has a constitutional unit represented by Formula (S) (constitutional unit derived from styrene).

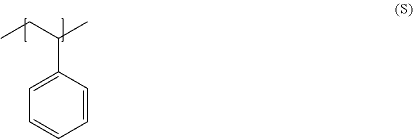

In a case where the binder polymer has the constitutional unit having an aromatic ring structure, the content of the constitutional unit having an aromatic ring structure is preferably 5% by mass to 90% by mass, more preferably 10% by mass to 70% by mass, and still more preferably 20% by mass to 60% by mass with respect to the all constitutional units of the binder polymer.

The binder polymer preferably has an aliphatic hydrocarbon ring structure. That is, the binder polymer preferably has a constitutional unit having an aliphatic hydrocarbon ring structure. The aliphatic hydrocarbon ring structure may be monocyclic or polycyclic. Among these, the binder polymer more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbornane ring, and an isophorone ring.

Among these, a ring in which two or more aliphatic hydrocarbon rings are fused is preferable, and a tetrahydrodicyclopentadiene ring (tricyclo[5.2.1.0^{2,6}]decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

In addition, the binder polymer more preferably has a constitutional unit represented by Formula (Cy), and more preferably has the above-described constitutional unit represented by Formula (S) and the constitutional unit represented by Formula (Cy).

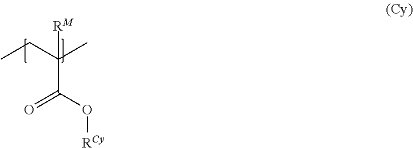

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

In addition, the aliphatic hydrocarbon ring structure in RC′ of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and still more preferably a tetrahydrodicyclopentadiene ring structure.

Furthermore, the aliphatic hydrocarbon ring structure in RC′ of Formula (Cy) is preferably a ring structure in which two or more aliphatic hydrocarbon rings are fused, and more preferably a ring in which two to four aliphatic hydrocarbon rings are fused.

Furthermore, R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The binder polymer may have one constitutional unit having an aliphatic hydrocarbon ring structure alone, or two or more kinds thereof.

In a case where the binder polymer has the constitutional unit having an aliphatic hydrocarbon ring structure, the content of the constitutional unit having an aliphatic hydrocarbon ring structure is preferably 5% by mass to 90% by mass, more preferably 10% by mass to 80% by mass, and still more preferably 20% by mass to 70% by mass with respect to the all constitutional units of the binder polymer.

In a case where the binder polymer has the constitutional unit having an aromatic ring structure and the constitutional unit having an aliphatic hydrocarbon ring structure, the total content of the constitutional unit having an aromatic ring structure and the constitutional unit having an aliphatic hydrocarbon ring structure is preferably 10% by mass to 90% by mass, more preferably 20% by mass to 80% by mass, and still more preferably 20% by mass to 50% by mass with respect to all constitutional units of the binder polymer.

The binder polymer preferably has a constitutional unit having an acid group.

Examples of the above-described acid group include a carboxy group, a sulfo group, a phosphonic acid group, and a phosphoric acid group, and a carboxy group is preferable.

As the above-described constitutional unit having an acid group, constitutional units derived from (meth)acrylic acid, which are shown below, is preferable, and a constitutional unit derived from methacrylic acid is more preferable.

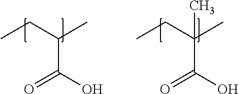

The binder polymer may have one constitutional unit having an acid group alone, or two or more kinds thereof.

In a case where the binder polymer has the constitutional unit having an acid group, the content of the constitutional unit having an acid group is preferably 5% by mass to 50% by mass, more preferably 5% by mass to 40% by mass, and still more preferably 10% by mass to 30% by mass with respect to the all constitutional units of the binder polymer.

The binder polymer preferably has a reactive group, and more preferably has a constitutional unit having a reactive group.

As the reactive group, a radically polymerizable group is preferable, and an ethylenically unsaturated group is more preferable. In addition, in a case where the binder polymer has an ethylenically unsaturated group, the binder polymer preferably has a constitutional unit having an ethylenically unsaturated group in the side chain.

In the present specification, the “main chain” represents a relatively longest binding chain in a molecule of a polymer compound constituting a resin, and the “side chain” represents an atomic group branched from the main chain.

As the ethylenically unsaturated group, an allyl group or a (meth)acryloxy group is more preferable.

Examples of the constitutional unit having a reactive group include those shown below, but the constitutional unit having a reactive group is not limited thereto.

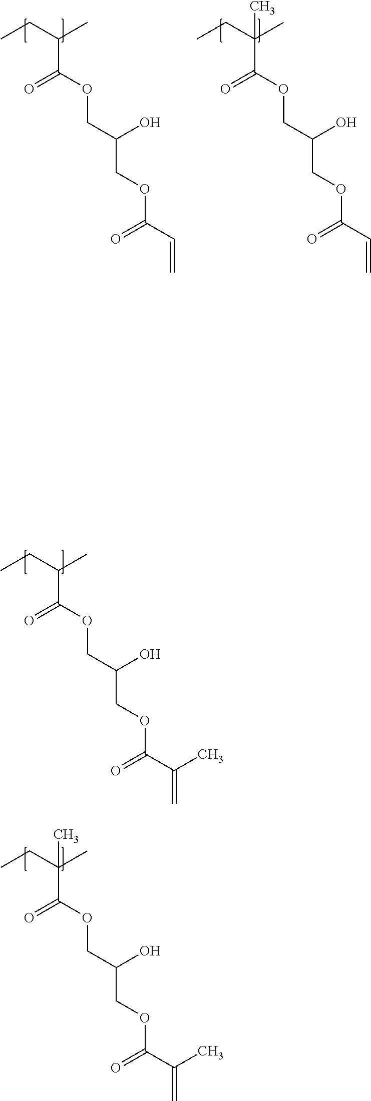

The binder polymer may have one constitutional unit having a reactive group alone, or two or more kinds thereof.

In a case where the binder polymer has the constitutional unit having a reactive group, the content of the constitutional unit having a reactive group is preferably 5% by mass to 70% by mass, more preferably 10% by mass to 50% by mass, and still more preferably 20% by mass to 40% by mass with respect to the all constitutional units of the binder polymer.

Examples of a method for introducing the reactive group into the binder polymer include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the binder polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the binder polymer, the following polymers are preferable. Content ratios (a to d) of each of the constitutional units shown below can be appropriately selected depending on the intended purpose within a range of weight-average molecular weight (Mw) described below.

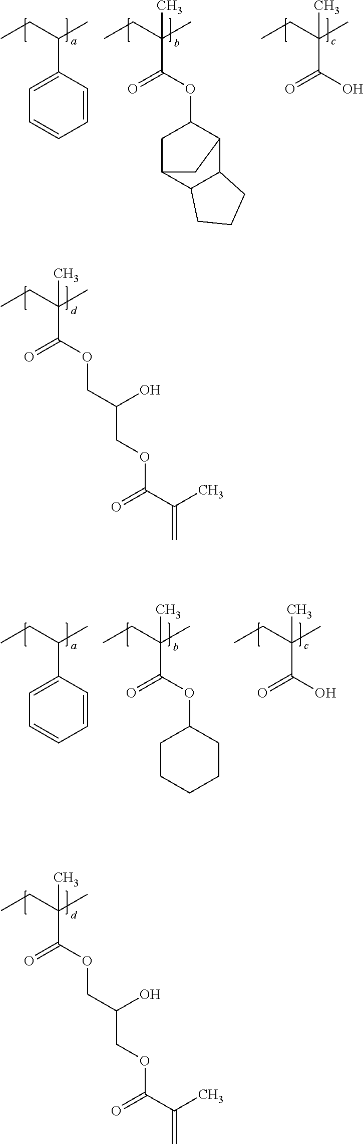

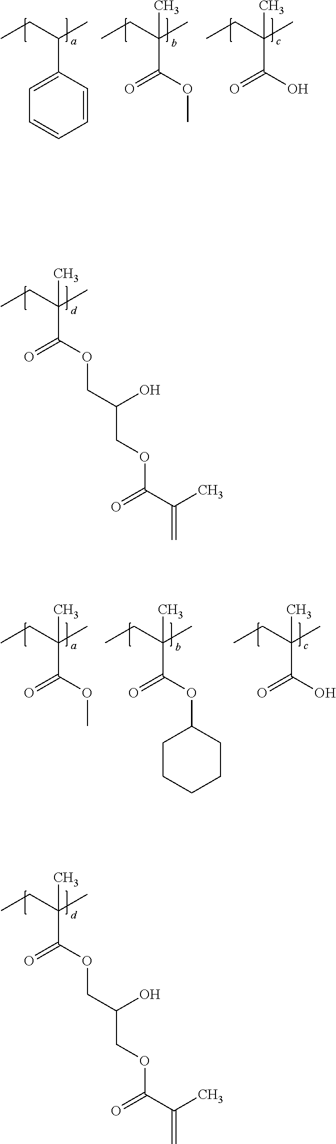

A weight-average molecular weight (Mw) of the binder polymer is preferably 5,000 or more, more preferably 10,000 or more, still more preferably 10,000 to 50,000, and particularly preferably 15,000 to 30,000.

An acid value of the binder polymer is preferably 10 mgKOH/g to 200 mgKOH/g, more preferably 60 mgKOH/g to 200 mgKOH/g, still more preferably 60 mgKOH/g to 150 mgKOH/g, and particularly preferably 60 mgKOH/g to 110 mgKOH/g.

The acid value of the binder polymer is a value measured according to the method described in JIS K0070: 1992.

The composition may contain only one kind of the binder polymer, or may contain two or more kinds thereof.

A content of the binder polymer is preferably 10% by mass to 90% by mass, more preferably 20% by mass to 80% by mass, and still more preferably 30% by mass to 70% by mass with respect to the total mass of the composition.

Polymerizable Compound

The composition according to the present disclosure contains a polymerizable compound.

The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter, also simply referred to as an “ethylenically unsaturated compound”).

As the ethylenically unsaturated group, a (meth)acryloxy group is preferable.

The ethylenically unsaturated compound in the present specification is a compound other than the above-described binder polymer, and preferably has a molecular weight of less than 5,000.

Examples of one suitable aspect of the polymerizable compound include a compound represented by Formula (M) (simply referred to as a “compound M”).

Q²-R¹-Q¹ Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) preferably have the same group.

In addition, from the viewpoint of reactivity, Q¹ and Q² in Formula (M) are preferably acryloyloxy groups.

R¹ in Formula (M) is preferably an alkylene group, an alkyleneoxyalkylene group (-L¹-O-L¹-), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms.

It is sufficient that the above-described hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable.

The above-described Li's each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

In addition, the number of atoms in the shortest linking chain which links Q¹ and Q² in the compound M is preferably 3 to 50, more preferably 4 to 40, still more preferably 6 to 20, and particularly preferably 8 to 12.

In the present specification, the “number of atoms in the shortest linking chain which links Q¹ and Q²” is the shortest number of atoms linking from an atom in R¹ linked to Q¹ to an atom in R₁ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture.

Among the above-described compounds, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is still more preferable.

In addition, examples of one suitable aspect of the polymerizable compound include a bi- or higher functional ethylenically unsaturated compound.

In the present specification, the “bi- or higher functional ethylenically unsaturated compound” means a compound having two or more ethylenically unsaturated groups in one molecule.

As the ethylenically unsaturated group in the ethylenically unsaturated compound, a (meth)acryloyl group is preferable.

As the ethylenically unsaturated compound, a (meth)acrylate compound is preferable.

The bifunctional ethylenically unsaturated compound is not particularly limited and can be appropriately selected from a known compound.

Examples of the bifunctional ethylenically unsaturated compound other than the above-described compound M include tricyclodecane dimethanol di(meth)acrylate, dioxane glycol di(meth)acrylate, and 1,4-cyclohexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), 1,6-hexanediol diacrylate (product name: NK ESTER A-HD-N, manufactured by Shin-Nakamura Chemical Co., Ltd.), and dioxane glycol diacrylate (KAYARAD R-604 manufactured by Nippon Kayaku Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the polymerizable compound also include a urethane (meth)acrylate compound.

Examples of the urethane (meth)acrylate include urethane di(meth)acrylate, and examples thereof include propylene oxide-modified urethane di(meth)acrylate and ethylene oxide and propylene oxide-modified urethane di(meth)acrylate.

In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name) manufactured by KYOEISHA CHEMICAL Co., LTD, UA-306H, UA-306T, UA-306I, UA-510H, and UX-5000 (all manufactured by Nippon Kayaku Co., Ltd.).

Examples of one suitable aspect of the polymerizable compound include an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 to 120 mgKOH/g)), and a penta- to hexa-functional ethylenically unsaturated compound having an acid group [component obtained by introducing a carboxy group to dipentaerythritol penta- and hexa-acrylate (DPHA) skeleton (acid value: 25 to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

Examples of the bi- or higher functional ethylenically unsaturated compound having a carboxy group include ARONIX (registered trademark) TO-2349 manufactured by Toagosei Co., Ltd., ARONIX (registered trademark) M-520 manufactured by Toagosei Co., Ltd., and ARONIX (registered trademark) M-510 manufactured by Toagosei Co., Ltd.

As the ethylenically unsaturated compound having an acid group, polymerizable compounds having an acid group, which are described in paragraphs to of JP2004-239942A, are preferable, and the contents described in this publication are incorporated in the present specification.

Examples of the polymerizable compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxyethyl-β′-(meth)acryloyloxyethyl-o-phthalate, and (meth)acrylic acid alkyl esters.

These compounds may be used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta(meth)acrylate, and dipentaerythritol hexa(meth)acrylate.

Among these, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

Examples of the polymerizable compound also include a caprolactone-modified compound of ethylenically unsaturated compound (for example, KAYARAD (registered trademark) DPCA-20 manufactured by Nippon Kayaku Co., Ltd., A-9300-1CL manufactured by Shin-Nakamura Chemical Co., Ltd., and the like), an alkylene oxide-modified compound of ethylenically unsaturated compound (for example, KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd., and the like).

Among these, as the polymerizable compound (particularly, the ethylenically unsaturated compound), from the viewpoint of excellent developability of the photosensitive composition layer after transfer, an ethylenically unsaturated compound including an ester bond is also preferable.

The ethylenically unsaturated compound including an ester bond is not particularly limited as long as it includes an ester bond in the molecule, but from the viewpoint that the effect of the present invention is excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the above-described ethylenically unsaturated compound having a tetramethylolmethane structure or a trimethylolpropane structure.

Examples of the ethylenically unsaturated compound having an aliphatic group having 6 to 20 carbon atoms include 1,9-nonanediol di(meth)acrylate, 1,10-decanediol di(meth)acrylate, and tricyclodecane dimethanol di(meth)acrylate.

Examples of one suitable aspect of the polymerizable compound include a polymerizable compound (preferably, a bifunctional ethylenically unsaturated compound) having an aliphatic hydrocarbon ring structure.

As the above-described polymerizable compound, a polymerizable compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable.

As the above-described aliphatic hydrocarbon ring structure, a cyclopentane structure, a cyclohexane structure, a tricyclodecane structure, a tricyclodecene structure, a norbornane structure, or an isophorone structure is preferable.

A molecular weight of the polymerizable compound is preferably 200 to 3,000, more preferably 250 to 2,600, still more preferably 280 to 2,200, and particularly preferably 300 to 2,200.

A proportion of a content of a polymerizable compound having a molecular weight of 300 or less in the polymerizable compounds included in the composition is preferably 30% by mass or less, more preferably 25% by mass or less, and still more preferably 20% by mass or less with respect to the content of all the polymerizable compounds included in the composition.

As one suitable aspect of the composition, the composition preferably includes the bi- or higher functional ethylenically unsaturated compound, more preferably includes the tri- or higher functional ethylenically unsaturated compound, and still more preferably includes a tri- or tetrafunctional ethylenically unsaturated compound.

In addition, as one suitable aspect of the composition, the composition preferably includes the bifunctional ethylenically unsaturated compound having an aliphatic hydrocarbon ring structure and the binder polymer having the constitutional unit having an aliphatic hydrocarbon ring.

In addition, as one suitable aspect of the composition, the composition preferably contains the compound represented by Formula (M) and the ethylenically unsaturated compound having an acid group, more preferably contains 1,9-nonanediol diacrylate, tricyclodecane dimethanol diacrylate, and a polyfunctional ethylenically unsaturated compound having a carboxylic acid group, and still more preferably contains 1,9-nonanediol diacrylate, tricyclodecane dimethanol diacrylate, and a succinic acid-modified form of dipentaerythritol pentaacrylate.

In addition, as one suitable aspect of the composition, from the viewpoint of development residue inhibitory property and rust preventive property, the composition preferably includes the bifunctional ethylenically unsaturated compound (preferably, a bifunctional (meth)acrylate compound) and the tri- or higher functional ethylenically unsaturated compound (preferably, a tri- or higher functional (meth)acrylate compound).

A mass ratio of a content of the bifunctional ethylenically unsaturated compound and a content of the tri- or higher functional ethylenically unsaturated compound is preferably to 90:10 and more preferably 30:70 to 70:30.

The content of the bifunctional ethylenically unsaturated compound is preferably 20% by mass to 80% by mass and more preferably 30% by mass to 70% by mass with respect to the total amount of all ethylenically unsaturated compounds.

The bifunctional ethylenically unsaturated compound in the composition is preferably 10% by mass to 60% by mass and more preferably 15% by mass to 40% by mass.

In addition, as one suitable aspect of the composition, the composition particularly preferably contains a bifunctional ethylenically unsaturated compound, a tri- or higher functional ethylenically unsaturated compound, and an ethylenically unsaturated compound having an acid group.

In addition, as one suitable aspect of the composition, the composition preferably contains 1,9-nonanediol diacrylate and a polyfunctional ethylenically unsaturated compound having a carboxylic acid group; more preferably contains 1,9-nonanediol diacrylate, tricyclodecane dimethanol diacrylate, and a polyfunctional ethylenically unsaturated compound having a carboxylic acid group; and still more preferably contains 1,9-nonanediol diacrylate, tricyclodecane dimethanol diacrylate, dipentaerythritol hexaacrylate, and a polyfunctional ethylenically unsaturated compound having a carboxylic acid group.

The composition may contain a monofunctional ethylenically unsaturated compound as the ethylenically unsaturated compound.

The content of the bi- or higher functional ethylenically unsaturated compound in the above-described ethylenically unsaturated compound is preferably 60% by mass to 100% by mass, more preferably 80% by mass to 100% by mass, and still more preferably 90% by mass to 100% by mass with respect to the total content of all ethylenically unsaturated compounds included in the composition.

The polymerizable compound (particularly, the ethylenically unsaturated compound) may be used alone or in combination of two or more kinds thereof.

A content of the polymerizable compound (particularly, the ethylenically unsaturated compound) in the composition is preferably 1% by mass to 70% by mass, more preferably 5% by mass to 70% by mass, still more preferably 5% by mass to 60% by mass, and particularly preferably 5% by mass to 50% by mass with respect to the total mass of the composition.

Polymer (X)

The polymer (X) includes a constitutional unit a represented by General Formula (A-1) or General Formula (A-2), and a constitutional unit β represented by General Formula (B).

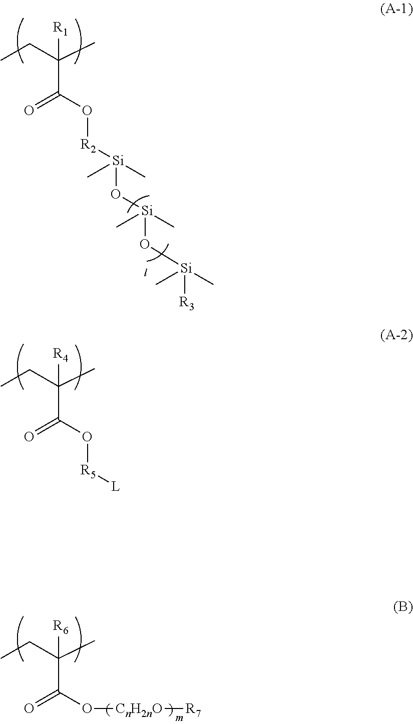

In General Formula (A-1), R₁ represents a hydrogen atom or a methyl group, R₂ represents an alkylene group having 1 to 10 carbon atoms, R₃ represents an alkyl group having 1 to 4 carbon atoms, and l represents an integer of 5 to 100.

In General Formula (A-2), R₄ represents a hydrogen atom or a methyl group, R₅ represents an alkylene group having 1 to 10 carbon atoms, and L represents a trimethylsilyl group or a tris(trimethylsiloxy)silyl group.

In General Formula (B), R₆ represents a hydrogen atom or a methyl group, R₇ represents a hydrogen atom or an alkyl group having 1 to 18 carbon atoms, m represents an integer of 1 to 100, and n represents an integer of 1 to 4.

In General Formula (A-1), R₁ represents a hydrogen atom or a methyl group.

From the viewpoint of thickness unevenness and film defects, R₁ is preferably a methyl group.

In General Formula (A-1), R₂ represents an alkylene group having 1 to 10 carbon atoms.

From the viewpoint of thickness unevenness and film defects, the alkylene group represented by R₂ is preferably an alkylene group having 1 to 5 carbon atoms, more preferably an alkylene group having 1 to 4 carbon atoms, and still more preferably an alkylene group having 1 to 3 carbon atoms.

From the viewpoint of thickness unevenness and film defects, examples of the alkylene group represented by R₂ include a methylene group, an ethylene group, a propylene group, and a butylene group; and a methylene group, an ethylene group, or a propylene group is preferable, an ethylene group or a propylene group is more preferable, and a propylene group is still more preferable.

In General Formula (A-1), R₃ represents an alkyl group having 1 to 4 carbon atoms.

From the viewpoint of thickness unevenness and film defects, the alkyl group represented by R₃ is preferably a methyl group, an ethyl group, a propyl group, or a butyl group, more preferably a methyl group or an ethyl group, and still more preferably a methyl group.

In General Formula (A-1), l represents an integer of 5 to 100, and from the viewpoint of thickness unevenness and film defects, l is preferably an integer of 5 to 60, more preferably an integer of 5 to 50, and still more preferably an integer of 20 to 40.

Specific examples of the constitutional unit represented by General Formula (A-1) are shown in Table 1 below, but the present disclosure is not limited thereto.

R₁, R₂, R₃, and l in Table 1 indicates R₁, R₂, R₃, and l in General Formula (A-1).

TABLE 1

| Constitutional unit | R₁ | R₂ | R₃ | l |
|---|---|---|---|---|
| A-1-1 | Methyl | Propylene | Methyl | 33 |
| | group | group | group | |
| A-1-2 | Methyl | Propylene | Methyl | 60 |
| | group | group | group | |
| A-1-3 | Methyl | Propylene | Butyl | 10 |
| | group | group | group | |
| A-1-4 | Methyl | Propylene | Methyl | 23 |
| | group | group | group | |
| A-1-5 | Methyl | Propylene | Methyl | 46 |
| | group | group | group | |
| A-1-6 | Methyl | Propylene | Butyl | 100 |
| | group | group | group | |
| A-1-7 | Hydrogen | Propylene | Methyl | 33 |
| | atom | group | group | |
| A-1-8 | Methyl | Propylene | Ethyl | 33 |
| | group | group | group | |
| A-1-9 | Methyl | Propylene | Propyl | 33 |
| | group | group | group | |
| A-1-10 | Methyl | Methylene | Methyl | 33 |
| | group | group | group | |
| A-1-11 | Methyl | Ethylene | Methyl | 33 |
| | group | group | group | |
| A-1-12 | Methyl | Butylene | Methyl | 33 |
| | group | group | group | |
| A-1-13 | Methyl | Hexylene | Methyl | 33 |
| | group | group | group | |
| A-1-14 | Methyl | Octylene | Methyl | 33 |
| | group | group | group | |
| A-1-15 | Methyl | Decylene | Methyl | 33 |
| | group | group | group | |

In General Formula (A-2), R₄ represents a hydrogen atom or a methyl group.

From the viewpoint of thickness unevenness and film defects, R₄ is preferably a methyl group.

In General Formula (A-2), R₅ represents an alkylene group having 1 to 10 carbon atoms.

From the viewpoint of thickness unevenness and film defects, the alkylene group represented by R₅ is preferably an alkylene group having 1 to 5 carbon atoms, more preferably an alkylene group having 1 to 4 carbon atoms, and still more preferably an alkylene group having 1 to 3 carbon atoms.

From the viewpoint of thickness unevenness and film defects, examples of the alkylene group represented by R₅ include a methylene group, an ethylene group, a propylene group, and a butylene group; and a methylene group, an ethylene group, or a propylene group is preferable, an ethylene group or a propylene group is more preferable, and an ethylene group is still more preferable.

Specific examples of the constitutional unit represented by General Formula (A-2) are shown in Table 2 below, but the present disclosure is not limited thereto.

R₄, R₅, and L in Table 2 indicates R₄, R₅, and L in General Formula (A-2).

In Table 2, “TMS group” means a trimethylsilyl group, and “TTMS group” means a tris(trimethylsiloxy)silyl group.

TABLE 2

| Constitutional unit | R₄ | R₅ | L |
|---|---|---|---|
| A-2-1 | Methyl group | Propylene group | TTMS group |
| A-2-2 | Methyl group | Propylene group | TMS group |
| A-2-3 | Hydrogen atom | Propylene group | TTMS group |
| A-2-4 | Hydrogen atom | Propylene group | TMS group |
| A-2-5 | Methyl group | Methylene group | TTMS group |
| A-2-6 | Methyl group | Ethylene group | TTMS group |
| A-2-7 | Methyl group | Butylene group | TTMS group |
| A-2-8 | Methyl group | Hexylene group | TTMS group |
| A-2-9 | Methyl group | Octylene group | TTMS group |
| A-2-10 | Methyl group | Decylene group | TTMS group |

In General Formula (B), R₆ represents a hydrogen atom or a methyl group.

From the viewpoint of thickness unevenness and film defects, R₆ is preferably a methyl group.

In General Formula (B), R₇ represents a hydrogen atom or an alkyl group having 1 to 18 carbon atoms.

From the viewpoint of thickness unevenness and film defects, the alkyl group represented by R₇ is preferably an alkyl group having 1 to 12 carbon atoms, more preferably an alkyl group having 1 to 4 carbon atoms, and still more preferably an alkyl group having 1 to 3 carbon atoms.

From the viewpoint of thickness unevenness and film defects, the alkyl group represented by R₇ is preferably a methyl group, an ethyl group, a propyl group, or a butyl group, more preferably a methyl group or an ethyl group, and still more preferably a methyl group.

In General Formula (B), m represents an integer of 1 to 100, and from the viewpoint of thickness unevenness and film defects, m is preferably an integer of 5 to 50, more preferably an integer of 7 to 30, and still more preferably an integer of 8 to 20.

In General Formula (B), n represents an integer of 1 to 4, and from the viewpoint of thickness unevenness and film defects, n is preferably an integer of 2 to 4, more preferably 2 or 3, and still more preferably 3.

Specific examples of General Formula (B) are shown in Table 3 below, but the present disclosure is not limited thereto.

R₆, R₇, m, and n in Table 3 indicates R₆, R₇, m, and n in General Formula (B).

TABLE 3

| Constitutional unit | R₆ | R₇ | m | n |
|---|---|---|---|---|
| B-1 | Methyl group | Hydrogen atom | 11 | 3 |
| B-2 | Methyl group | Hydrogen atom | 8 | 3 |
| B-3 | Methyl group | Hydrogen atom | 11 | 2 |
| B-4 | Methyl group | Hydrogen atom | 11 | 4 |
| B-5 | Hydrogen atom | Hydrogen atom | 11 | 3 |
| B-6 | Methyl group | Ethyl group | 11 | 3 |
| B-7 | Methyl group | Butyl group | 11 | 3 |
| B-8 | Methyl group | Decyl group | 11 | 3 |
| B-9 | Methyl group | Octadecyl group | 11 | 3 |
| B-10 | Methyl group | Hydrogen atom | 2 | 3 |
| B-11 | Methyl group | Hydrogen atom | 20 | 3 |
| B-12 | Methyl group | Hydrogen atom | 50 | 3 |
| B-13 | Methyl group | Hydrogen atom | 80 | 3 |
| B-14 | Methyl group | Hydrogen atom | 100 | 3 |

From the viewpoint of thickness unevenness and film defects, a mass ratio of the constitutional unit a and the constitutional unit β (constitutional unit α:constitutional unit β) is preferably 5:95 to 95:5, more preferably 10:90 to 50:50, and still more preferably 25:75 to From the viewpoint of thickness unevenness and film defects, a number-average molecular weight (Mn) of the polymer (X) is preferably 3,000 to 20,000, more preferably 5,000 to 15,000, and still more preferably 7,000 to 10,000.

From the viewpoint of thickness unevenness and film defects, it is preferable that the polymer (X) includes a polymer (X-1) including the constitutional unit represented by General Formula (A-1) described above and the constitutional unit represented by General Formula (B) described above, and a polymer (X-2) including the constitutional unit represented by General Formula (A-2) described above and the constitutional unit represented by General Formula (B) described above.

The polymer (X-1) is a polymer including the constitutional unit represented by General Formula (A-1) described above and the constitutional unit represented by General Formula (B) described above.

Preferred aspects of the constitutional unit represented by General Formula (A-1) and the constitutional unit represented by General Formula (B), which are included in the polymer (X-1), are as described above.

Specific examples of the polymer (X-1) are shown in Table 4 below, but the present disclosure is not limited thereto.

In addition, in Table 4, the “Type” described in the lower column of the constitutional unit represented by General Formula (A-1) is the same as the specific example of the constitutional unit represented by General Formula (A-1), shown in Table 1.

The “Type” described in the lower column of the constitutional unit represented by General Formula (B) is the same as the specific example of the constitutional unit represented by General Formula (B), shown in Table 3.

In addition, the “Content (% by mass)” indicates the mass of the constitutional unit represented by General Formula (A-1) or the constitutional unit represented by General Formula (B) with respect to the total mass of constitutional units included in the polymer (X-1).

In addition, the “Molecular weight” indicates the number-average molecular weight (Mn).

TABLE 4

| | Constitutional unit represented by | | Constitutional unit represented by | | |
|---|---|---|---|---|---|
| | General Formula (A-1) | | General Formula (B) | | |
| | | Content | | Content | Molecular |
| Polymer | Type | (% by mass) | Type | (% by mass) | weight |
| X-1-1 | A-1-1 | 19 | B-1 | 81 | 7500 |
| X-1-2 | A-1-2 | 29 | B-1 | 71 | 7500 |
| X-1-3 | A-1-1 | 23 | B-3 | 77 | 7500 |
| X-1-4 | A-1-1 | 16 | B-4 | 84 | 7500 |
| X-1-5 | A-1-3 | 8 | B-1 | 92 | 7500 |
| X-1-6 | A-1-4 | 14 | B-1 | 86 | 7500 |
| X-1-7 | A-1-5 | 24 | B-1 | 76 | 7500 |
| X-1-8 | A-1-6 | 40 | B-1 | 60 | 7500 |
| X-1-9 | A-1-7 | 19 | B-1 | 81 | 7500 |
| X-1-10 | A-1-8 | 19 | B-1 | 81 | 7500 |
| X-1-11 | A-1-9 | 19 | B-1 | 81 | 7500 |
| X-1-12 | A-1-10 | 19 | B-1 | 81 | 7500 |
| X-1-13 | A-1-11 | 19 | B-1 | 81 | 7500 |
| X-1-14 | A-1-12 | 19 | B-1 | 81 | 7500 |
| X-1-15 | A-1-13 | 19 | B-1 | 81 | 7500 |
| X-1-16 | A-1-14 | 19 | B-1 | 81 | 7500 |
| X-1-17 | A-1-15 | 19 | B-1 | 81 | 7500 |
| X-1-18 | A-1-1 | 19 | B-5 | 81 | 7500 |
| X-1-19 | A-1-1 | 18 | B-6 | 82 | 7500 |
| X-1-20 | A-1-1 | 18 | B-7 | 82 | 7500 |
| X-1-21 | A-1-1 | 16 | B-8 | 84 | 7500 |
| X-1-22 | A-1-1 | 15 | B-9 | 85 | 7500 |
| X-1-23 | A-1-1 | 45 | B-10 | 55 | 7500 |
| X-1-24 | A-1-1 | 12 | B-11 | 88 | 7500 |
| X-1-25 | A-1-1 | 5 | B-12 | 95 | 7500 |
| X-1-26 | A-1-1 | 3 | B-13 | 97 | 7500 |
| X-1-27 | A-1-1 | 3 | B-14 | 97 | 7500 |

The polymer (X-2) is a polymer including the constitutional unit represented by General Formula (A-2) described above and the constitutional unit represented by General Formula (B) described above.

Preferred aspects of the constitutional unit represented by General Formula (A-2) and the constitutional unit represented by General Formula (B), which are included in the polymer (X-2), are as described above.

Specific examples of the polymer (X-2) are shown in Table 5 below, but the present disclosure is not limited thereto.

In addition, in Table 5, the “Type” described in the lower column of the constitutional unit represented by General Formula (A-2) is the same as the specific example of the constitutional unit represented by General Formula (A-2), shown in Table 2.

The “Type” described in the lower column of the constitutional unit represented by General Formula (B) is the same as the specific example of the constitutional unit represented by General Formula (B), shown in Table 3.

In addition, the “Content (% by mass)” indicates the mass of the constitutional unit represented by General Formula (A-2) or the constitutional unit represented by General Formula (B) with respect to the total mass of constitutional units included in the polymer (X-2).

In addition, the “Molecular weight” indicates the number-average molecular weight (Mn).

TABLE 5

| | Constitutional unit represented by | | Constitutional unit represented by | | |
|---|---|---|---|---|---|
| | General Formula (A-2) | | General Formula (B) | | |
| | | Content | | Content | Molecular |
| Polymer | Type | (% by mass) | Type | (% by mass) | weight |
| X-2-1 | A-2-1 | 23 | B-2 | 77 | 9500 |
| X-2-2 | A-2-1 | 3 | B-2 | 97 | 9500 |
| X-2-3 | A-2-1 | 5 | B-2 | 95 | 9500 |
| X-2-4 | A-2-1 | 50 | B-2 | 50 | 9500 |
| X-2-5 | A-2-1 | 95 | B-2 | 5 | 9500 |
| X-2-6 | A-2-1 | 97 | B-2 | 3 | 9500 |
| X-2-7 | A-2-1 | 23 | B-2 | 77 | 9500 |
| X-2-8 | A-2-2 | 12 | B-2 | 88 | 9500 |
| X-2-9 | A-2-3 | 22 | B-2 | 78 | 9500 |
| X-2-10 | A-2-4 | 12 | B-2 | 88 | 9500 |
| X-2-11 | A-2-5 | 22 | B-2 | 78 | 9500 |
| X-2-12 | A-2-6 | 22 | B-2 | 78 | 9500 |
| X-2-13 | A-2-7 | 24 | B-2 | 76 | 9500 |
| X-2-14 | A-2-8 | 25 | B-2 | 75 | 9500 |
| X-2-15 | A-2-9 | 26 | B-2 | 74 | 9500 |
| X-2-16 | A-2-10 | 27 | B-2 | 73 | 9500 |
| X-2-17 | A-2-1 | 18 | B-1 | 82 | 9500 |
| X-2-18 | A-2-1 | 22 | B-3 | 78 | 9500 |
| X-2-19 | A-2-1 | 16 | B-4 | 84 | 9500 |
| X-2-20 | A-2-1 | 19 | B-5 | 81 | 9500 |
| X-2-21 | A-2-1 | 18 | B-6 | 82 | 9500 |
| X-2-22 | A-2-1 | 17 | B-7 | 83 | 9500 |
| X-2-23 | A-2-1 | 16 | B-8 | 84 | 9500 |
| X-2-24 | A-2-1 | 14 | B-9 | 86 | 9500 |
| X-2-25 | A-2-1 | 45 | B-10 | 55 | 9500 |
| X-2-26 | A-2-1 | 12 | B-11 | 88 | 9500 |
| X-2-27 | A-2-1 | 5 | B-12 | 95 | 9500 |
| X-2-28 | A-2-1 | 3 | B-13 | 97 | 9500 |
| X-2-29 | A-2-1 | 3 | B-14 | 97 | 9500 |

A mass ratio of the polymer (X-1) and the polymer (X-2) (polymer (X-1):polymer (X-2)) is preferably 5:95 to 95:5, more preferably 10:90 to 50:50, and still more preferably 20:80 to 40:60.

From the viewpoint of thickness unevenness and film defects, a number-average molecular weight (Mn) of the polymer (X-1) is preferably 3,000 to 20,000, more preferably 5,000 to 10,000, and still more preferably 7,000 to 9,000.

From the viewpoint of thickness unevenness and film defects, a number-average molecular weight (Mn) of the polymer (X-2) is preferably 3,000 to 20,000, more preferably 7,000 to 15,000, and still more preferably 9,000 to 11,000.

A content of the polymer (X) is preferably more than 0.05% by mass and less than 1.5% by mass, more preferably 0.10% by mass or more and 1.2% by mass or less, and still more preferably 0.2% by mass or more and 1.0% by mass or less with respect to the total mass of the composition.

Solvent

The composition according to the embodiment of the present disclosure contains a solvent.

As the solvent, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

In addition, as the solvent, an organic solvent (high-boiling-point solvent) having a boiling point of 180° C. to 250° C. can also be used, as necessary.

The solvent may be used alone or in combination of two or more kinds thereof.

A content of the solvent in the composition is preferably 20% by mass or more and 95% by mass or less, more preferably 60% by mass or more and 95% by mass or less, and still more preferably 70% by mass or more and 95% by mass or less with respect to the total mass of the composition.

Polymerization Initiator

The composition according to the present disclosure may contain a polymerization initiator.

As the polymerization initiator, a photopolymerization initiator is preferable.

The photopolymerization initiator is not particularly limited and a known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-amino alkylphenone-based photopolymerization initiator, and the N-phenylglycine-based photopolymerization initiator.

In addition, as the photopolymerization initiator, for example, polymerization initiators described in paragraphs [0031] to [0042] of JP2011-95716A and paragraphs to of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzo yl)-9H-carbazol-3-yl]ethanone-1-(O-acetyloxime) [product name: IRGACURE (registered trademark) OXE-02, manufactured by BASF SE], IRGACURE (registered trademark) OXE-03 (manufactured by BASF SE), IRGACURE (registered trademark) OXE-04 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V.], 2-benzyl-2-dimethylamino-1-(4-morpholinophenyl)butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PB G-305, manufactured by TRONLY), 1,2-propanedione, 3-cyclohexyl-1-[9-ethyl-6-(2-furanylcarbonyl)-9H-carbazole-3-yl]-, 2-(0-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The photopolymerization initiator may be used alone or in combination of two or more kinds thereof. In a case of using two or more kinds thereof, it is preferable to use at least one selected from the oxime-based photopolymerization initiator, the α-aminoalkylphenone-based photopolymerization initiator, or the α-hydroxyalkylphenone-based photopolymerization initiator.

In a case where the composition contains the photopolymerization initiator, a content of the photopolymerization initiator is preferably 0.1% by mass or more, more preferably 0.5% by mass or more, and still more preferably 1.0% by mass or more with respect to the total mass of the composition. In addition, the upper limit thereof is preferably 10% by mass or less and more preferably 5% by mass or less with respect to the total mass of the composition.

Heterocyclic Compound

The composition according to the present disclosure may contain a heterocyclic compound.

A heterocyclic ring included in the heterocyclic compound may be either a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

Among the above-described compounds, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Thermal Crosslinking Compound

From the viewpoint of hardness of a cured film to be obtained and pressure-sensitive adhesiveness of an uncured film to be obtained, the composition according to the embodiment of the present disclosure preferably contains a thermal crosslinking compound. In the present specification, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened.

The blocked isocyanate compound refers to a “compound having a structure in which the isocyanate group of isocyanate is protected (so-called masked) with a blocking agent”.

From the viewpoint of improving brittleness of the film and improving the adhesion to the object to be transferred, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable.

The blocked isocyanate compound may have a polymerizable group.

The polymerizable group is not particularly limited, and a known polymerizable group can be used, and a radically polymerizable group is preferable.

Examples of the polymerizable group include a (meth)acryloxy group, a (meth)acrylamide group, an ethylenically unsaturated group such as styryl group, and an epoxy group such as a glycidyl group.

Among these, as the polymerizable group, an ethylenically unsaturated group is preferable, a (meth)acryloxy group is more preferable, and an acryloxy group still more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) SBN-70D, DURANATE (registered trademark) WT32-B75P, and the like manufactured by Asahi Kasei Corporation).

The thermal crosslinking compound may be used alone or in combination of two or more kinds thereof.

In a case where the composition contains the thermal crosslinking compound, a content of the thermal crosslinking compound is preferably 1% by mass to 50% by mass and more preferably 5% by mass to 30% by mass with respect to the total mass of the composition.

Other Components

The composition according to the present disclosure may contain a component other than the above-mentioned components (hereinafter also referred to as “other components”). Examples of the other components include a colorant, an antioxidant, and particles (for example, metal oxide particles). In addition, examples of the other components also include other additives described in paragraphs [0058] to [0071] of JP2000-310706A.

Producing Method of Composition According to Embodiment of Present Disclosure

A producing method of the composition according to the embodiment of the present disclosure is not particularly limited, and the composition according to the embodiment of the present disclosure can be produced by mixing the binder polymer, the polymerizable compound, the polymer (X), and the solvent.

Transfer Film

The transfer film according to the embodiment of the present disclosure includes a temporary support and a photosensitive composition layer in this order, in which the photosensitive composition layer is a layer formed of the composition according to the embodiment of the present disclosure.

Temporary Support

The transfer film includes a temporary support.

The temporary support is a member which supports the photosensitive composition layer, and is finally removed by a peeling treatment.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable.

Examples of the above-described film include a polyethylene terephthalate film (for example, a biaxial stretching polyethylene terephthalate film), a polymethylmethacrylate film, a cellulose triacetate film, a polystyrene film, a polyimide film, and a polycarbonate film.

Among these, as the temporary support, a polyethylene terephthalate film is preferable.

In addition, it is preferable that the film used as the temporary support does not have deformation such as wrinkles or scratches.

From the viewpoint that exposure in a patterned manner through the temporary support can be performed, the temporary support preferably has high transparency, and the transmittance at 313 nm, 365 nm, 405 nm, and 436 nm is preferably 60% or more, more preferably 70% or more, still more preferably 80% or more, and most preferably 90% or more.

A thickness of the temporary support is not particularly limited, but is preferably 5 μm to 200 μm. In addition, from the viewpoint of ease of handling and general-purpose properties, the thickness of the temporary support is more preferably 5 μm to 150 μm, still more preferably 5 μm to 50 μm, and most preferably 5 μm to 25 μm.

The thickness of the temporary support is calculated as an average value of any five points measured by a cross-sectional observation with a scanning electron microscope (SEM).

In order to improve adhesiveness between the temporary support and the photosensitive composition layer, a side of the temporary support in contact with the photosensitive composition layer may be surface-modified by UV irradiation, corona discharge, plasma, or the like.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

The temporary support may be a recycled product. Examples of the recycled product include films obtained washing used films and the like into chips and using the chips as a material. Specific examples of the recycled product include Ecouse series of Toray Industries, Inc.

A preferred aspect of the temporary support is described in, for example, paragraphs [0017] and [0018] of JP2014-085643A, paragraphs to of JP2016-027363A, paragraphs [0041] to [0057] of WO2012/081680A, and paragraphs to of WO2018/179370A, the contents of which are incorporated herein by reference.

From the viewpoint of imparting handleability, a layer (lubricant layer) including fine particles may be provided on the surface of the temporary support. The lubricant layer may be provided on one surface of the temporary support, or on both surfaces thereof. A diameter of the particles included in the lubricant layer is preferably 0.05 μm to 0.8 μm.

In addition, a film thickness of the lubricant layer is preferably 0.05 μm to 1.0 μm.

Examples of a commercially available product of the temporary support include LUMIRROR 16KS40, LUMIRROR 16FB40, LUMIRROR #38-U48, LUMIRROR #75-U34, and LUMIRROR #25-T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

Photosensitive Composition Layer

The transfer film according to the embodiment of the present disclosure includes a photosensitive composition layer.

The photosensitive composition layer is a layer formed of the composition according to the embodiment of the present disclosure.

A pattern can be formed on the object to be transferred by transferring the photosensitive composition layer onto the object to be transferred followed by performing exposure and development.

As the photosensitive composition layer, a negative tone is preferable. Incidentally, the negative tone photosensitive composition layer is a photosensitive composition layer having a solubility in a developer which decreases by exposure to an exposed portion.

The photosensitive composition layer is obtained, for example, by applying the composition according to the embodiment of the present disclosure to form a coating film, and then drying the coating film.

Therefore, components contained in the photosensitive composition layer are the same as the components which can be contained in the composition according to the embodiment of the present disclosure, and preferred aspects thereof are also the same.

Preferred aspects of contents of the components contained in the photosensitive composition layer are as follows.

From the viewpoint of thickness unevenness and film defects, a content of the binder polymer is preferably 10% by mass to 90% by mass, more preferably 20% by mass to 80% by mass, and still more preferably 30% by mass to 70% by mass with respect to the total mass of the photosensitive composition layer.

From the viewpoint of thickness unevenness and film defects, a content of the polymerizable compound is preferably 1% by mass to 70% by mass, more preferably 5% by mass to 70% by mass, still more preferably 5% by mass to 60% by mass, and particularly preferably 5% by mass to 50% by mass with respect to the total mass of the photosensitive composition layer.

From the viewpoint of thickness unevenness and film defects, a content of the polymer (X) is preferably 0.01% by mass to 3.0% by mass, more preferably 0.01% by mass to 1.0% by mass, and still more preferably 0.05% by mass to 0.80% by mass with respect to the total mass of the photosensitive composition layer.

A content of the solvent is preferably 0% by mass to 3.0% by mass, more preferably 0% by mass to 1.0% by mass, and still more preferably 0% by mass to 0.80% by mass with respect to the total mass of the photosensitive composition layer.

A thickness of the photosensitive composition layer is not particularly limited, but from the viewpoint that the effects of the present invention are more excellent, is often 30 μm or less, preferably 20 μm or less, more preferably 15 μm or less, still more preferably 10 μm or less, and particularly preferably 5.0 μm or less. From the viewpoint that hardness of a film obtained by curing the photosensitive composition layer is excellent, the lower limit is preferably 0.60 μm or more and more preferably 1.5 μm or more.

That is, the thickness of the photosensitive composition layer is preferably 0.60 μm or more and 20 μm or less, more preferably 1.5 μm or more and 15 μm or less, and particularly preferably 1.5 μm or more and 5.0 μm or less.

For example, the thickness of the photosensitive composition layer is obtained as an average value of 5 random points measured by cross-sectional observation with a scanning electron microscope (SEM).

A visible light transmittance of the photosensitive composition layer at a film thickness of approximately 1.0 μm is preferably 80% or more, more preferably 90% or more, and most preferably 95% or more.

As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above.

Examples of a preferred value of the transmittance include 87%, 92%, and 98%.

Protective Film

The transfer film according to the embodiment of the present disclosure may include a protective film.

As the protective film, a resin film having heat resistance and solvent resistance can be used, and examples thereof include polyolefin films such as a polypropylene film and a polyethylene film, polyester films such as a polyethylene terephthalate film, polycarbonate films, and polystyrene films.

In addition, as the protective film, a resin film formed of the same material as in the above-described temporary support may be used.

Among these, as the protective film, a polyolefin film is preferable, a polypropylene film or a polyethylene film is more preferable, and a polyethylene film is still more preferable.

A thickness of the protective film is preferably 1 μm to 100 μm, more preferably 5 μm to 50 μm, still more preferably 5 μm to 40 μm, and particularly preferably 15 μm to 30 μm.

From the viewpoint of excellent mechanical hardness, the thickness of the protective film is preferably 1 μm or more, and from the viewpoint of relatively low cost, the thickness of the protective film is preferably 100 μm or less.

Refractive Index Adjusting Layer

The transfer film according to the embodiment of the present disclosure may include a refractive index adjusting layer.

As the refractive index adjusting layer, a known refractive index adjusting layer can be adopted. Examples of a material included in the refractive index adjusting layer include a binder polymer, the polymerizable compound, a metal salt, and particles.

A method for controlling a refractive index of the refractive index adjusting layer is not particularly limited, and examples thereof include a method using a resin having a predetermined refractive index alone, a method using a resin and particles, and a method using a composite body of a metal salt and a resin.

It is preferable that the refractive index of the refractive index adjusting layer is higher than the refractive index of the photosensitive composition layer.

The refractive index of the refractive index adjusting layer is preferably 1.50 or more, more preferably 1.55 or more, still more preferably 1.60 or more, and particularly preferably 1.65 or more. The upper limit of the refractive index of the refractive index adjusting layer is preferably 2.10 or less, more preferably 1.85 or less, and still more preferably 1.78 or less.

A thickness of the refractive index adjusting layer is preferably 50 to 500 nm, more preferably 55 to 110 nm, and still more preferably 60 to 100 nm.

The thickness of the refractive index adjusting layer is obtained as an average value of 5 random points measured by cross-sectional observation with a scanning electron microscope (SEM).

Example of Embodiment of Transfer Film

Hereinafter, an example according to the embodiment of the transfer film will be described.

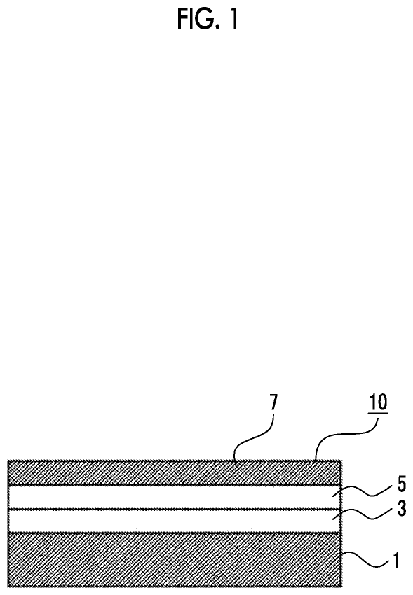

A transfer film 10 shown in FIG. 1 includes a temporary support 1, a photosensitive composition layer 3, a refractive index adjusting layer 5, and a protective film 7 in this order.

The transfer film 10 shown in FIG. 1 is in a form in which the protective film 7 is disposed, but the protective film 7 may not be disposed.

In addition, the transfer film 10 shown in FIG. 1 is in a form in which the refractive index adjusting layer 5 is disposed, but the refractive index adjusting layer 5 may not be disposed.

Manufacturing Method of Transfer Film

The manufacturing method of the transfer film according to the embodiment of the present disclosure is not particularly limited, and a known method can be used.

Examples of the manufacturing method of the above-described transfer film 10 include a method including a step of applying the composition according to the embodiment of the present disclosure onto a surface of the temporary support 1 to form a coating film and then drying the coating film to form the photosensitive composition layer 3 and a step of applying a composition for forming a refractive index adjusting layer onto a surface of the photosensitive composition layer 3 to form a coating film and then drying the coating film to form the refractive index adjusting layer 5.

The protective film 7 is subjected to pressure bonding to the refractive index adjusting layer 5 of the laminate manufactured by the manufacturing method described above, whereby the transfer film 10 is manufactured.

In the manufacturing method of the transfer film of the first embodiment, it is preferable to manufacture the transfer film 10 including the temporary support 1, the photosensitive composition layer 3, the refractive index adjusting layer 5, and the protective film 7 by including a step of providing the protective film 7 so as to be in contact with the surface of the refractive index adjusting layer 5 opposite to the side having the temporary support 1.

After manufacturing the transfer film 10 by the above-described manufacturing method, a roll-shaped transfer film may be manufactured and stored by winding the transfer film 10. The roll-shaped transfer film is provided as it is in a bonding step described later with the substrate in a roll-to-roll method.

In addition, as the manufacturing method of the above-described transfer film 10, a method of forming the photosensitive resin layer 13 on the surface of the refractive index adjusting layer 5 after forming the refractive index adjusting layer 5 on the protective film 7 may be used.

In addition, as the manufacturing method of the above-described transfer film 10, a method in which the photosensitive composition layer 3 is formed on the temporary support 1, the refractive index adjusting layer 5 is separately formed on the protective film 7, and the refractive index adjusting layer 5 is bonded to the photosensitive composition layer 3 may be used.

Forming Method of Photosensitive Composition Layer

From the viewpoint of excellent productivity, it is desirable that the photosensitive composition layer in the transfer film is formed by a coating method using the above-described composition according to the embodiment of the present disclosure.

Specifically, as the manufacturing method of the transfer film, a method in which the composition according to the embodiment of the present disclosure is applied onto the temporary support to form a coating film, and the coating film is dried at a predetermined temperature to form the photosensitive composition layer is preferable.

Examples of a method for applying the photosensitive composition include a printing method, a spray coating method, a roll coating method, a bar coating method, a curtain coating method, a spin coating method, and a die coating method (that is, a slit coating method).

As a method of drying the coating film, heat drying or vacuum drying is preferable. In the present specification, the “drying” means removing at least a part of the solvent included in the composition. Examples of the drying method include natural drying, heat drying, and vacuum drying. The above-described methods can be adopted alone or in combination of two or more thereof.

The drying temperature is preferably 80° C. or higher and more preferably 90° C. or higher. In addition, the upper limit value thereof is preferably 130° C. or lower and more preferably 120° C. or lower. The drying can be performed by continuously changing the temperature.

In addition, the drying time is preferably 20 seconds or more, more preferably 40 seconds or more, and still more preferably 60 seconds or more. In addition, the upper limit value thereof is not particularly limited, but is preferably 600 seconds or less, and more preferably 300 seconds or less.

Forming Method of Refractive Index Adjusting Layer

The composition for forming a refractive index adjusting layer preferably includes various components forming the above-described refractive index adjusting layer and a solvent.

The solvent is not particularly limited as long as it can dissolve or disperse the components included in the refractive index adjusting layer, and at least one selected from the group consisting of water and a water-miscible organic solvent is preferable, water or a mixed solvent of water and a water-miscible organic solvent is more preferable.

Examples of the water-miscible organic solvent include an alcohol having 1 to 3 carbon atoms, acetone, ethylene glycol, and glycerin, and an alcohol having 1 to 3 carbon atoms is preferable and methanol or ethanol is more preferable.

The solvent may be used alone, or in combination of two or more kinds thereof.

A content of the solvent is preferably 50 parts by mass to 2,500 parts by mass, more preferably 50 parts by mass to 1,900 parts by mass, and still more preferably 100 parts by mass to 900 parts by mass with respect to 100 parts by mass of the total solid content of the composition.

The forming method of the refractive index adjusting layer is not particularly limited as long as it is a method capable of forming a layer including the components, and examples thereof include known coating methods (slit coating, spin coating, curtain coating, ink jet coating, and the like).

In addition, by bonding a protective film to the refractive index adjusting layer, the transfer film of the first embodiment can be manufactured.

A method of bonding the protective film to the refractive index adjusting layer is not particularly limited, and a known method can be mentioned.

Examples of an apparatus for bonding the protective film to the refractive index adjusting layer include known laminators such as a vacuum laminator and an auto-cut laminator.

It is preferable that the laminator is equipped with any heatable roller such as a rubber roller and can perform pressurization and heating.

Use of Transfer Film

The transfer film according to the embodiment of the present disclosure can be applied to various applications.

For example, the transfer film according to the embodiment of the present invention can be applied to an electrode protective film, an insulating film, a flattening film, an overcoat film, a hard coat film, a passivation film, a partition wall, a spacer, a microlens, an optical filter, an antireflection film, an etching resist, a plating member, or the like.

More specific examples thereof include a protective film or an insulating film for a touch panel electrode, a protective film or an insulating film for a printed wiring board, a protective film or an insulating film for a TFT substrate, a color filter, an overcoat film for a color filter, and an etching resist for a wiring line formation.

Among these, the transfer film according to the embodiment of the present disclosure is preferably used for manufacturing a touch panel.

Manufacturing Method of Laminate

Hereinafter, the manufacturing method of a laminate will be described in detail, and a photosensitive composition layer and a refractive index adjusting layer are collectively referred to as a composition layer.

The manufacturing method of a laminate according to the embodiment of the present disclosure includes a bonding step of bringing a surface of the transfer film according to the embodiment of the present disclosure opposite to the temporary support into contact with a substrate having a conductive layer to bond the transfer film to the substrate, to obtain a photosensitive composition layer-attached substrate including the substrate, the conductive layer, the photosensitive composition layer, and the temporary support in this order; an exposing step of exposing the photosensitive composition layer in a patterned manner; and a developing step of developing the exposed photosensitive composition layer to form a protective film pattern which protects the conductive layer, in which a peeling step of peeling off the temporary support from the photosensitive composition layer-attached substrate is provided between the bonding step and the exposing step or between the exposing step and the developing step.

The manufacturing method of a laminate according to the embodiment of the present disclosure in a case of including a refractive index adjusting layer includes a bonding step of bringing a surface of the transfer film according to the embodiment of the present disclosure opposite to the temporary support into contact with a substrate having a conductive layer to bond the transfer film to the substrate, to obtain a composition layer-attached substrate including the substrate, the conductive layer, the refractive index adjusting layer, the photosensitive composition layer, and the temporary support in this order; an exposing step of exposing the refractive index adjusting layer and the photosensitive composition layer in a patterned manner; and a developing step of developing the exposed refractive index adjusting layer and photosensitive composition layer to form a protective film pattern which protects the conductive layer, in which a peeling step of peeling off the temporary support from the composition layer-attached substrate is provided between the bonding step and the exposing step or between the exposing step and the developing step.

Hereinafter, as an example, the manufacturing method of a laminate according to the embodiment of the present disclosure in a case of including a refractive index adjusting layer will be described.

Bonding Step

The bonding step is a step of bringing a surface of the transfer film opposite to the temporary support into contact with a substrate having a conductive portion to bond the transfer film to the substrate, to obtain a composition layer-attached substrate including the substrate, the conductive layer, the composition layer, and the temporary support in this order. In a case where the transfer film has a configuration of having the protective film, the protective film is peeled off and then the bonding step is performed.

In the above-described bonding, the conductive layer and the surface of the composition layer are pressure-bonded so that both are in contact with each other.

The above-described pressure-bonding method is not particularly limited, and a known transfer method and laminating method can be used. Among these, it is preferable that the surface of the composition layer is superposed on the substrate having a conductive portion, and pressurization and heating are performed by a roll or the like.

A known laminator such as a vacuum laminator and an auto-cut laminator can be used for the bonding.

A laminating temperature is not particularly limited, but is preferably, for example, to 130° C.

The substrate having a conductive layer has a conductive layer on the substrate, and any layer may be formed as necessary. That is, the substrate having the conductive layer is a conductive substrate having at least a substrate and a conductive layer arranged on the substrate.

Examples of the substrate include a resin substrate, a glass substrate, and a semiconductor substrate.

A preferred aspect of the substrate is described, for example, in paragraph of WO2018/155193A, the contents of which are incorporated herein by reference. As a material of the resin substrate, a cycloolefin polymer or polyimide is preferable. A thickness of the resin substrate is preferably 5 μm to 200 μm and more preferably 10 μm to 100 μm.

As the conductive layer, from the viewpoint of conductivity and fine line formability, at least one layer selected from the group consisting of a metal layer, a conductive metal oxide layer, a graphene layer, a carbon nanotube layer, and a conductive polymer layer is preferable.

In addition, only one conductive layer may be disposed, or two or more conductive layers may be arranged on the substrate. In a case where two or more conductive layers are arranged, it is preferable to have conductive layers formed of different materials.

A preferred aspect of the conductive layer is described, for example, in paragraph [0141] of WO2018/155193A, the contents of which are incorporated herein by reference.

As the substrate having a conductive layer, a substrate having at least one of a transparent electrode or a lead wire is preferable. Such a substrate can be suitably used as a substrate for a touch panel.

The transparent electrode can function suitably as an electrode for a touch panel. The transparent electrode is preferably composed of a metal oxide film such as indium tin oxide (ITO) and indium zinc oxide (IZO), a metal mesh, and a fine metal wire such as a metal nanowire.

Examples of the fine metal wire include thin wire of silver and copper. Among these, silver conductive materials such as silver mesh and silver nanowire are preferable. As a material of the lead wire, metal is preferable.

Examples of a metal which is a material of the lead wire include gold, silver, copper, molybdenum, aluminum, titanium, chromium, zinc, manganese, and alloy consisting of two or more kinds of these metal elements. As the material of the lead wire, copper, molybdenum, aluminum, or titanium is preferable, copper is particularly preferable.

It is preferable that the electrode protective film for a touch panel, which is formed by using the composition layer in the transfer film according to the embodiment of the present disclosure, is provided so as to cover the electrode and the like directly or through other layers, in order to protect the electrode and the like (that is, at least one of the electrode for a touch panel or the wire for a touch panel).

Exposing Step

The exposing step is a step of exposing the composition layer in a patterned manner.

Here, the “exposure in a patterned manner” refers to exposure in a form of performing the exposure in a patterned manner, that is, a form in which an exposed portion and a non-exposed portion are present.

A positional relationship between the exposed portion and the non-exposed portion in the exposure in a patterned manner is not particularly limited and is appropriately adjusted.

The exposure may be performed from the side opposite to the substrate of the composition layer, or may be performed from the substrate side of the composition layer.

As a light source of the exposure in a patterned manner, a light source can be appropriately selected, as long as it can emit light at a wavelength region (for example, 365 nm or 405 nm) at which at least the photosensitive composition layer can be cured. Among these, a main wavelength of the exposure light for the exposure in a patterned manner is preferably 365 nm. The main wavelength is a wavelength having the highest intensity.

Examples of the light source include various lasers; semiconductor light sources such as a light emitting diode (LED); and discharge lamps such as an ultra-high pressure mercury lamp, a high pressure mercury lamp, and a metal halide lamp.

An exposure amount is preferably 5 to 200 mJ/cm² and more preferably 10 to 200 mJ/cm².

In a case where the composition layer is provided on the substrate using the transfer film, the exposure in a patterned manner may be performed after the temporary support is peeled off from the composition layer, or before peeling off the temporary support, the exposure in a patterned manner may be performed through the temporary support, and then the temporary support may be peeled off. From the viewpoint of preventing mask contamination due to contact between the composition layer and the mask and viewpoint of avoiding an influence of foreign substance adhering to the mask on the exposure, it is preferable to perform the exposure without peeling off the temporary support. From the viewpoint of improving resolution by suppressing scattering of exposure light by the temporary support and suppressing diffraction of light transmitted through the mask, it is preferable to perform the exposure after peeling off the temporary support.

The exposure in a patterned manner may be an exposure through the mask or a direct exposure using a laser or the like.

Examples of a base material of the mask in a case of exposure through an exposure mask include a quartz mask, a soda-lime glass mask, and a film mask. Among these, from the viewpoint of excellent dimensional accuracy, a quartz mask is preferable, and from the viewpoint that it is easy to increase the size, a film mask is preferable. As the base material of the film mask, a polyester film is preferable, and a polyethylene terephthalate film is more preferable. Specific examples of the base material of the film mask include XPR-7S SG (manufactured by Fujifilm Global Graphic Systems).

Suitable aspects of the light source, the exposure amount, and the exposing method used for the exposure are described in, for example, paragraphs [0146] and [0147] of WO2018/155193A, the contents of which are incorporated herein by reference.

By performing the exposing step and the developing step described later, a protective film pattern (cured film) which protects at least a part of the conductive layer is formed on the conductive layer on the substrate.

Peeling Step

The peeling step is a step of peeling off the temporary support from the composition layer-attached substrate between the bonding step and the exposing step, or between the exposing step and the developing step described later.

The peeling method is not particularly limited, and the same mechanism as the cover film peeling mechanism described in paragraphs [0161] and [0162] of JP2010-072589A can be used.

Developing Step

The developing step is a step of developing the exposed composition layer to form a pattern (cured film).

The development of the above-described composition layer can be performed using a developer.

As the developer, an alkali aqueous solution is preferable. Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

Examples of the development method include methods such as puddle development, shower development, spin development, and dip development.

Examples of the developer which is suitably used in the present specification include the developer described in paragraph [0194] of WO2015/093271A, and examples of the developing method which is suitably used include the developing method described in paragraph [0195] of WO2015/093271A.

Post-Exposing Step and Post-Baking Step

The above-described manufacturing method of a laminate may include a step of exposing the pattern obtained by the above-described developing step (post-exposing step) and/or a step of heating (post-baking step) the pattern.

In a case where both of the post-exposing step and the post-baking step are included, it is preferable that the post-baking is performed after the post-exposure.

An exposure amount in the post-exposure is preferably 100 mJ/cm² to 5000 mJ/cm² and more preferably 200 mJ/cm² to 3000 mJ/cm².

A temperature of the post-baking is preferably 80° C. to 250° C. and more preferably 90° C. to 160° C.

A post-baking time is preferably 1 minute to 180 minutes and more preferably 10 minutes to 60 minutes.

Use of Laminate

The laminate manufactured by the manufacturing method of a laminate according to the embodiment of the present invention can be applied to various devices. Examples of the device provided with the above-described laminate include a display device, a printed wiring board, a semiconductor package, and an input device, and a touch panel is preferable, and a capacitance type touch panel is more preferable. In addition, the above-described input device can be applied to a display device such as an organic electroluminescent display device and a liquid crystal display device.

In a case where the laminate is applied to a touch panel, it is preferable that the pattern formed from the composition layer is used as a protective film for an electrode for a touch panel or a wiring line for a touch panel. That is, it is preferable that the composition layer included in the transfer film is used for formation of a protective film of an electrode for a touch panel or a protective film of a wiring line for a touch panel.

Cured Film

The cured film according to the embodiment of the present disclosure is obtained by curing at least a part of the photosensitive composition layer.

Examples of a method of curing at least a part of the photosensitive composition layer include curing by light or heat, and from the viewpoint of forming a pattern into a desired shape, curing by exposure in a patterned manner is more preferable.

For the method of exposure in a patterned manner, preferred aspects in the exposing step of the above-described manufacturing method of a laminate can be referred to.

Device

The device according to the embodiment of the present disclosure includes a cured film.

Examples of the device according to the embodiment of the present disclosure include the device provided with the laminate, described in <Use of laminate> above.

### EXAMPLES

Examples will be described below, but the present invention is not limited to these examples. In the following description, unless otherwise specified, “parts” and “%” are all based on mass.

Synthesis of Polymer X-1-1

150 parts of butyl acetate was charged into a 1000 ml reaction container equipped with a stirrer, a reflux condenser, a dropping funnel, a thermometer, and a nitrogen gas blowing port, and then refluxed while nitrogen gas was introduced. Under the condition that the butyl acetate was refluxed, 300 parts of a dropping solution shown below was added dropwise thereto at a constant rate over 2 hours using the dropping funnel.

After 1 hour from the completion of the dropwise addition of the dropping solution, 1.5 parts of t-amylperoxy-2-ethylhexanoate was added thereto, and the mixture was further reacted for 2 hours while maintaining the reflux temperature to synthesize a polymer X-1-1. After the completion of the reaction, a concentration of the polymer X-1-1 was adjusted with butyl acetate, and a solution containing the polymer X-1-1 (the mass of the polymer X-1-1 with respect to the mass of the entire solution was 30% by mass) was obtained.

The number-average molecular weight of the synthesized polymer X-1-1 in terms of polystyrene by gel permeation chromatograph was 7,500.

Composition of Dropping Solution
Monomer represented by Formula (a-1-1): 57 parts
Monomer represented by Formula (b-1): 243 parts

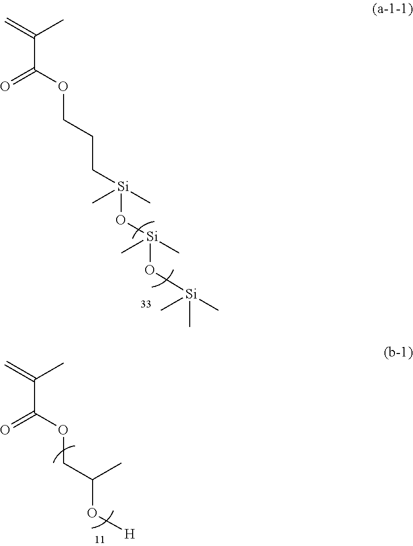

Synthesis of Polymer X-1-2

A polymer X-1-2 was synthesized by the same procedure as the synthesis of the polymer X-1-1, except that the composition of the dropping solution was changed as follows. The number-average molecular weight thereof was 7,500.

Composition of Dropping Solution
Monomer represented by Formula (a-1-2): 87 parts
Monomer represented by Formula (b-1): 213 parts

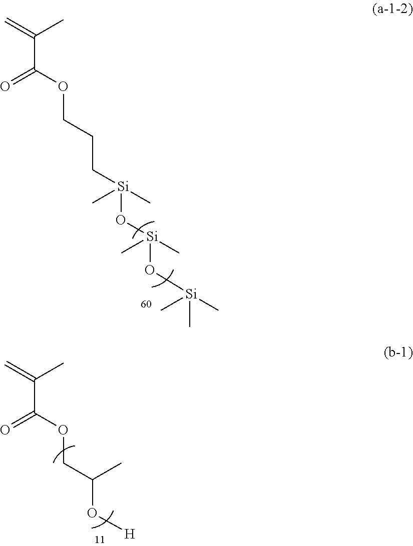

Synthesis of Polymer X-1-3

A polymer X-1-3 was synthesized by the same procedure as the synthesis of the polymer X-1-1, except that the composition of the dropping solution was changed as follows. The number-average molecular weight thereof was 7,500.

Composition of Dropping Solution
Monomer represented by Formula (a-1-1): 69 parts
Monomer represented by Formula (b-3): 231 parts

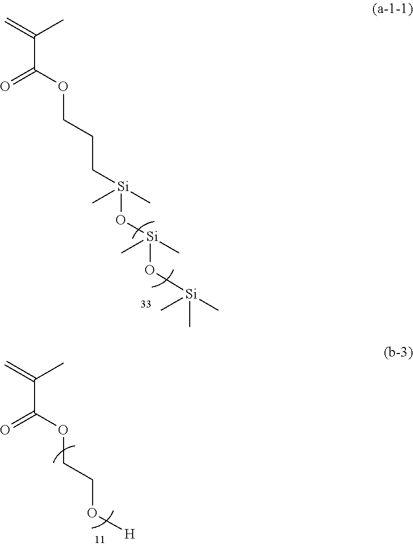

Synthesis of Polymer X-1-4

A polymer X-1-4 was synthesized by the same procedure as the synthesis of the polymer X-1-1, except that the composition of the dropping solution was changed as follows. The number-average molecular weight thereof was 7,500.

Composition of Dropping Solution
Monomer represented by Formula (a-1-1): 48 parts
Monomer represented by Formula (b-4): 252 parts

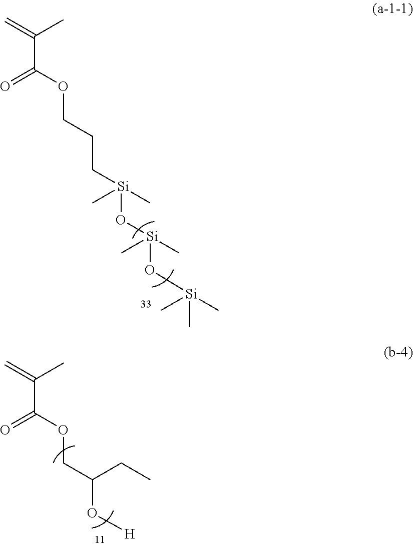

Synthesis of Polymer X-2-1

A polymer X-2-1 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 69 parts
Monomer represented by Formula (b-2): 231 parts

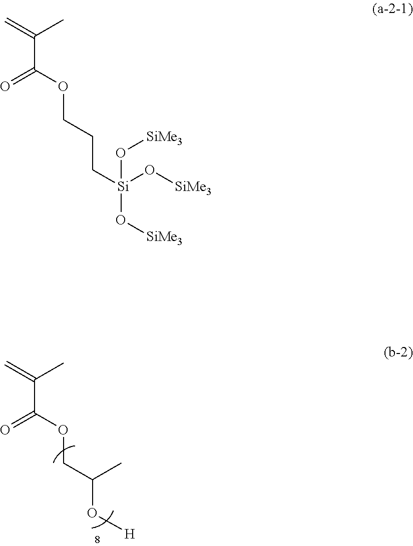

Synthesis of polymer X-2-2

A polymer X-2-2 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 9 parts
Monomer represented by Formula (b-2): 291 parts

Synthesis of Polymer X-2-3

A polymer X-2-3 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 15 parts
Monomer represented by Formula (b-2): 285 parts

Synthesis of Polymer X-2-4

A polymer X-2-4 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 150 parts
Monomer represented by Formula (b-2): 150 parts

Synthesis of Polymer X-2-5

A polymer X-2-5 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 285 parts
Monomer represented by Formula (b-2): 15 parts

Synthesis of Polymer X-2-6

A polymer X-2-6 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 291 parts
Monomer represented by Formula (b-2): 9 parts

Synthesis of Polymer X-2-7

A polymer X-2-7 was synthesized by the same procedure as the synthesis of the polymer X-1-1, except that the composition of the dropping solution was changed as follows. The number-average molecular weight thereof was 9,500.

Composition of Dropping Solution
Monomer represented by Formula (a-2-1): 69 parts
Monomer represented by Formula (b-2): 231 parts

Synthesis of Polymer CX-1

A polymer CX-1 was synthesized by the same procedure as the synthesis of the polymer X-1-1, except that the composition of the dropping solution was changed as follows. The number-average molecular weight thereof was 7,500.

Composition of Dropping Solution
Monomer represented by Formula (ca-1): 12 parts
Monomer represented by Formula (b-1): 288 parts

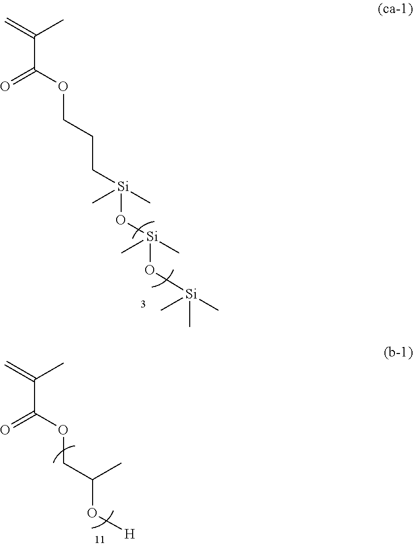

### Examples 1 to 25, and 28 to 31, and Comparative Examples 1 to 3

Preparation of Composition

Components as shown in Tables 6 to 8 were mixed to obtain a mixture. A mixed solvent of methyl ethyl ketone (MEK) and propylene glycol monomethyl ether acetate (PGMEA) (MEK/PGMEA=60%/40%) was added to the mixture to obtain a composition having a concentration of solid contents of 25%.

The content of each component in Tables 6 to 8 is the mass (unit: % by mass) of each component in the mixture with respect to the mass of the entire mixture.

Production of Transfer Film

Immediately after stirring the composition for 30 minutes, the composition was applied onto a polyethylene terephthalate film (temporary support, LUMIRROR 16KS40, Toray Industries, Inc., thickness: 16 μm) using a slit-shaped nozzle, and the solvent was removed by drying the coating liquid with a hot air convection dryer having a temperature gradient of 75° C. to 120° C., to form a photosensitive composition layer on the temporary support. The coating amount of the photosensitive composition was adjusted so that the thickness of the photosensitive composition layer after drying was 5.8 μm.

Next, a protective film (LUMIRROR 16KS40, Toray Industries, Inc., thickness: 16 μm) was pressure-bonded onto the photosensitive composition layer, thereby producing a transfer film including the temporary support, the photosensitive composition layer, and the protective film in this order.

### Example 26

A photosensitive composition layer was formed on the temporary support by the same procedure as in Example 5. Thereafter, the following composition for forming a refractive index adjusting layer was further applied onto the photosensitive composition layer so as to adjust the thickness after drying to be 73 nm, and then dried at 80° C. for 1 minute. Thereafter, the composition was further dried at 110° C. for 1 minute to form a refractive index adjusting layer directly disposed on the photosensitive composition layer. Next, a protective film (LUMIRROR 16KS40, Toray Industries, Inc., thickness: 16 μm) was pressure-bonded onto the refractive index adjusting layer, thereby producing a transfer film including the temporary support, the photosensitive composition layer, the refractive index adjusting layer, and the protective film in this order.

Composition for Forming Refractive Index Adjusting Layer

The composition for forming a refractive index adjusting layer was prepared using each of the following components.

The composition for forming a refractive index adjusting layer was an aqueous resin composition which was prepared using a resin having an acid group and an ammonia aqueous solution, in which the resin having an acid group was neutralized with the ammonia aqueous solution to contain an ammonium salt of the resin having an acid group.
Metal oxide particles (ZrO₂ particles, NanoUse OZ-S30M, concentration of solid contents: 30.5% by mass, methanol: 69.5% by mass, refractive index: 2.2, average particle diameter: approximately 12 nm, manufactured by Nissan Chemical Corporation): 80.84 parts by mass expressed in terms of solid contents
Binder polymer having acid group (acrylic resin, ZB-015M, manufactured by FUJIFILM Fine Chemicals Co., Ltd., copolymer resin of methacrylic acid/allyl methacrylate (compositional ratio (molar ratio)=20/80), weight-average molecular weight: 25,000, concentration of solid contents: 5.00%, ammonia aqueous solution): 9.02 parts by mass expressed in terms of solid contents
Binder polymer having acid group (acrylic resin, ARUFON UC3920, manufactured by Toagosei Co., Ltd.): 0.54 parts by mass
Ethylenically unsaturated compound (polyfunctional ethylenically unsaturated compound having a carboxylic acid group, ARONIX TO-2349, manufactured by Toagosei Co., Ltd.): 2.05 parts by mass
Monoisopropanolamine (manufactured by MITSUI FINE CHEMICAL Inc.): 1.33 parts by mass
Amino alcohol MDA (manufactured by NIPPON NYUKAZAI CO., LTD.): 2.05 parts by mass
Adenine (manufactured by Tokyo Chemical Industry Co., Ltd.): 2.05 parts by mass
Surfactant (silicone-based surfactant, BYK-348, manufactured by BYK Chemie): 2.12 parts by mass
Mixed solvent of methanol and distilled water (methanol:distilled water=7:3 (mass ratio)): amount at which the concentration of solid contents of the composition for forming a refractive index adjusting layer was 1.62% by mass

### Example 27

A transfer film was produced by the same procedure as in Example 1, except that the Preparation of composition was performed in the following procedure.

Preparation of Composition

Components as shown in Table 8 were mixed to obtain a mixture. A mixed solvent of methyl ethyl ketone (MEK) and propylene glycol monomethyl ether acetate (PGMEA) (MEK/PGMEA=60%/40%) was added to the mixture to obtain a composition having a concentration of solid contents of 29%.

Production of Laminate

Bonding Step

The protective film was peeled off from a test piece of the obtained transfer film, and the peeled surface was brought into contact with a copper substrate and bonded to obtain a bonded body.

Exposing Step

Next, the photosensitive composition layer of the bonded body was exposed from the temporary support side (condition: 150 mJ/cm² (i-rays)).

Peeling Step

After the exposure, the support film was peeled off.

Developing Step

The product was immersed in a 1% by mass sodium carbonate solution with a liquid temperature of 35° C. at 35° C. for 50 seconds for development.

Post-Exposing Step and Post-Baking Step

After the development, exposure was carried out (condition: 400 mJ/cm² (i-rays)) from the photosensitive layer side. Furthermore, heat treatment was performed at 150° C. for minutes using an oven to obtain a laminate in which a film (hereinafter, a cured film) obtained by curing the photosensitive composition layer was laminated on the copper substrate.

Evaluation

Evaluation of Thickness Unevenness

A thickness of the cured film was measured by observation with a scanning electron microscope (SEM), thickness unevenness (%) was calculated based on the following expression (1), and the thickness unevenness of the cured film was evaluated based on the following evaluation standard.

In Expression (1), the thickness is an average thickness obtained by arithmetically averaging thicknesses of the cured films at any five locations measured using SEM.

Thickness unevenness (%)={(Maximum thickness−Minimum thickness)/Thickness}×100 Expression (1):

In the following evaluation standard, practically, “C” or higher is preferable, “B” or higher is more preferable, and “A” is most preferable.

Evaluation Standard
“A”: less than 1%
“B”: 1% or more and less than 3%
“C”: 3% or more and less than 5%
“D”: 5% or more and less than 10%
“E”: 10% or more

Evaluation of Bubble Defects

The laminate was observed from the cured film side using an optical microscope, and bubble defects (which may be on the surface of the cured film or inside of the cured film) appeared to be circular were evaluated based on the following evaluation standard. In the following evaluation standard, practically, “C” or higher is preferable, “B” or higher is more preferable, and “A” is most preferable.

Evaluation Standard
“A”: no bubble defects were observed.
“B”: bubble defects having a diameter of 0.1 μm or less were observed.
“C”: bubble defects having a diameter of more than 0.1 μm and 0.5 μm or less were observed.
“D”: bubble defects having a diameter of more than 0.5 μm and 1 μm or less were observed.

Evaluation of Adhesiveness

The laminate was allowed to stand in an environment of 110° C. and 85% RH for 24 hours.

Thereafter, a cross-cut test of 100 squares was carried out with reference to JIS standard (K5400-8.5). The cured film which was a test surface of the laminate was cut with a 1 mm square grid using a cutter knife, a transparent adhesive tape #600 (manufactured by 3M) was strongly pressure-bonded thereon, and then peeled off in a direction of 180°, a state of the square grid was visually observed, and adhesiveness was evaluated based on the following evaluation standard. In the following evaluation standard, practically, “C” or higher is preferable, “B” or higher is more preferable, and “A” is most preferable.

Evaluation Standard
“A”: no peeling of the cured film occurred.
“B”: slight peeling occurred only in the vicinity of the notch.
“C”: peeling occurred only in the vicinity of the notch.
“D”: a part of the peeling occurred without depending on the notch.
“E”: the entire surface was peeled off, and no cured film remained.

Evaluation of Copper Corrosion

The laminate was allowed to stand in an environment of 110° C. and 85% RH for 24 hours.

Thereafter, discoloration of the copper substrate was observed with an optical microscope. Evaluation was carried out based on the following evaluation standard. In the following evaluation standard, practically, “C” or higher is preferable, “B” or higher is more preferable, and “A” is most preferable.

Evaluation Standard
“A”: no discoloration occurred.
“B”: discoloration was slightly observed.
“C”: discoloration was observed.
“D”: discoloration was remarkably observed.
“E”: discoloration was remarkably observed, and a part of the cured film was peeled off from the copper substrate.

TABLE 6

| | | Example | Example | Example | Example | Example | Example | Example | Example | Example | Example | Example |
|---|---|---|---|---|---|---|---|---|---|---|---|---|
| | | 1 | 2 | 3 | 4 | 5 | 6 | 7 | 8 | 9 | 10 | 11 |
| Binder polymer | | 52.63 | 52.63 | 52.63 | 52.63 | 52.63 | 52.63 | 52.63 | 52.63 | 52.63 | 52.63 | 52.63 |
| Polymerizable | ADCP | 17.89 | 17.89 | 17.89 | 17.89 | 17.89 | 17.89 | 17.89 | 17.89 | 17.89 | 17.89 | 17.89 |
| compound | TO2349 | 2.98 | 2.98 | 2.98 | 2.98 | 2.98 | 2.98 | 2.98 | 2.98 | 2.98 | 2.98 | 2.98 |
| | A-NOD-N | 2.73 | 2.73 | 2.73 | 2.73 | 2.73 | 2.73 | 2.73 | 2.73 | 2.73 | 2.73 | 2.73 |
| | DPHA | 7.99 | 7.99 | 7.99 | 7.99 | 7.99 | 7.99 | 7.99 | 7.99 | 7.99 | 7.99 | 7.99 |
| Photopolymerization | OXE-02 | 0.36 | 0.36 | 0.36 | 0.36 | 0.36 | 0.36 | 0.36 | 0.36 | 0.36 | 0.36 | 0.36 |
| initiator | Irg 907 | 0.73 | 0.73 | 0.73 | 0.73 | 0.73 | 0.73 | 0.73 | 0.73 | 0.73 | 0.73 | 0.73 |
| Other components | NPG | 0.10 | 0.10 | 0.10 | 0.10 | 0.10 | 0.10 | 0.10 | 0.10 | 0.10 | 0.10 | 0.10 |
| Crosslinking compound | WT32-B75P | 12.50 | 12.50 | 12.50 | 12.50 | 12.50 | 12.50 | 12.50 | 12.50 | 12.50 | 12.50 | 12.50 |
| Other components | Benzimidazole | 0.13 | 0.13 | 0.13 | 0.13 | 0.13 | 0.13 | 0.13 | 0.13 | 0.13 | 0.13 | 0.13 |
| | Isonicotinamide | 0.52 | 0.52 | 0.52 | 0.52 | 0.52 | 0.52 | 0.52 | 0.52 | 0.52 | 0.52 | 0.52 |
| | XIRAN EF40 | 1.20 | 1.20 | 1.20 | 1.20 | 1.20 | 1.20 | 1.20 | 1.20 | 1.20 | 1.20 | 1.20 |
| Polymer (X-1) | Type | X-1-1 | — | X-1-1 | X-1-1 | X-1-1 | X-1-1 | X-1-1 | X-1-1 | X-1-1 | X-1-1 | X-1-1 |
| | Amount | 0.24 | — | 0.02 | 0.04 | 0.05 | 0.12 | 0.22 | 0.05 | 0.05 | 0.05 | 0.05 |
| Polymer (X-2) | Type | — | X-2-1 | X-2-1 | X-2-1 | X-2-1 | X-2-1 | X-2-1 | X-2-3 | X-2-4 | X-2-5 | X-2-7 |
| | Amount | — | 0.24 | 0.22 | 0.20 | 0.19 | 0.12 | 0.02 | 0.19 | 0.19 | 0.19 | 0.19 |
| Amount ratio (X-1):(X-2) | | — | — | 5:95 | 10:90 | 20:80 | 50:50 | 95:5 | 20:80 | 20:80 | 20:80 | 20:80 |
| Fluorine-based | F551A | — | — | — | — | — | — | — | — | — | — | — |
| surfactant | | | | | | | | | | | | |
| Evaluation | Thickness | C | C | B | A | A | A | B | A | A | A | A |
| | unevenness | | | | | | | | | | | |
| | Bubble defects | A | A | A | A | A | A | A | A | A | A | A |
| | Adhesiveness | B | B | B | A | A | A | B | A | A | A | A |
| | Copper corrosion | B | B | B | A | A | A | B | A | A | A | A |

TABLE 7

| | | Example | Example | Example | Example | Example | Example | Example | Example | Example | Example | Example |
|---|---|---|---|---|---|---|---|---|---|---|---|---|
| | | 12 | 13 | 14 | 15 | 16 | 17 | 18 | 19 | 20 | 21 | 22 |
| Binder polymer | | 52.63 | 52.63 | 52.63 | 52.63 | 52.63 | 52.63 | 52.63 | 52.63 | 52.63 | 52.63 | 52.63 |
| Polymerizable | ADCP | 17.89 | 17.89 | 17.89 | 17.89 | 17.89 | 17.89 | 17.89 | 17.89 | 17.89 | 17.89 | 17.89 |
| compound | TO2349 | 2.98 | 2.98 | 2.98 | 2.98 | 2.98 | 2.98 | 2.98 | 2.98 | 2.98 | 2.98 | 2.98 |
| | A-NOD-N | 2.73 | 2.73 | 2.73 | 2.73 | 2.73 | 2.73 | 2.73 | 2.73 | 2.73 | 2.73 | 2.73 |
| | DPHA | 7.99 | 7.99 | 7.99 | 7.99 | 7.99 | 7.99 | 7.99 | 7.99 | 7.99 | 7.99 | 7.99 |
| Photopolymerization | OXE-02 | 0.36 | 0.36 | 0.36 | 0.36 | 0.36 | 0.36 | 0.36 | 0.36 | 0.36 | 0.36 | 0.36 |
| initiator | Irg 907 | 0.73 | 0.73 | 0.73 | 0.73 | 0.73 | 0.73 | 0.73 | 0.73 | 0.73 | 0.73 | 0.73 |
| Other components | NPG | 0.10 | 0.10 | 0.10 | 0.10 | 0.10 | 0.10 | 0.10 | 0.10 | 0.10 | 0.10 | 0.10 |
| Crosslinking | WT32-B75P | 12.50 | 12.50 | 12.50 | 12.50 | 12.50 | 12.50 | 12.50 | 12.50 | 12.50 | 12.50 | 12.50 |
| compound | | | | | | | | | | | | |
| Other components | Benzimidazole | 0.13 | 0.13 | 0.13 | 0.13 | 0.13 | 0.13 | 0.13 | 0.13 | 0.13 | 0.13 | 0.13 |
| | Isonicotinamide | 0.52 | 0.52 | 0.52 | 0.52 | 0.52 | 0.52 | 0.52 | 0.52 | 0.52 | 0.52 | 0.52 |
| | XIRAN EF40 | 1.20 | 1.20 | 1.20 | 1.20 | 1.20 | 1.20 | 1.20 | 1.20 | 1.20 | 1.20 | 1.20 |
| Polymer (X-1) | Type | X-1-1 | X-1-1 | X-1-1 | X-1-1 | X-1-1 | — | — | — | — | — | — |
| | Amount | 0.02 | 0.08 | 0.2 | 0.05 | 1.5 | — | — | — | — | — | — |
| Polymer (X-2) | Type | X-2-1 | X-2-1 | X-2-1 | — | — | X-2-2 | X-2-3 | X-2-4 | X-2-5 | X-2-6 | X-2-7 |
| | Amount | 0.08 | 0.32 | 0.80 | — | — | 0.24 | 0.24 | 0.24 | 0.24 | 0.24 | 0.24 |
| Amount ratio (X-1):(X-2) | | 20:80 | 20:80 | 20:80 | — | — | — | — | — | — | — | — |
| Fluorine-based | F551A | — | — | — | — | — | — | — | — | — | — | — |
| surfactant | | | | | | | | | | | | |
| Evaluation | Thickness | A | A | A | D | B | D | C | C | C | C | C |
| | unevenness | | | | | | | | | | | |
| | Bubble defects | A | A | A | A | C | A | A | A | A | C | A |
| | Adhesiveness | A | A | A | A | C | A | A | A | B | C | B |
| | Copper corrosion | A | A | A | C | C | C | B | B | B | D | B |

TABLE 8

| | | | | | Compar- | Compar- | Compar- | | | | | | |
|---|---|---|---|---|---|---|---|---|---|---|---|---|---|
| | | | | | ative | ative | ative | | | | | | |
| | | Example | Example | Example | Example | Example | Example | Example | Example | Example | Example | Example | Example |
| | | 23 | 24 | 25 | 1 | 2 | 3 | 26 | 27 | 28 | 29 | 30 | 31 |
| Binder | A | 52.63 | 52.63 | 52.63 | 52.63 | 52.63 | 52.63 | 52.63 | — | 52.35 | 52.64 | | |
| polymer | B | — | — | — | — | — | — | — | 53.60 | — | — | — | — |
| | C | — | — | — | — | — | — | — | — | — | — | 48.72 | 49.00 |
| Polymer- | ADCP | 17.89 | 17.89 | 17.89 | 17.89 | 17.89 | 17.89 | 17.89 | 19.30 | 17.79 | 17.89 | 9.07 | 9.12 |
| izable | TO2349 | 2.98 | 2.98 | 2.98 | 2.98 | 2.98 | 2.98 | 2.98 | 3.22 | 2.96 | 2.98 | 3.02 | 3.04 |
| compound | A-NOD-N | 2.73 | 2.73 | 2.73 | 2.73 | 2.73 | 2.73 | 2.73 | — | 2.72 | 2.73 | 2.77 | 2.79 |
| | DPHA | 7.99 | 7.99 | 7.99 | 7.99 | 7.99 | 7.99 | 7.99 | — | 7.94 | 7.98 | 17.17 | 17.27 |
| | 8UX-015A | — | — | — | — | — | — | — | 9.65 | — | — | — | — |
| Photopoly- | OXE-02 | 0.36 | 0.36 | 0.36 | 0.36 | 0.36 | 0.36 | 0.36 | 0.37 | 0.36 | 0.36 | 0.37 | 0.37 |
| merization | Irg 907 | 0.73 | 0.73 | 0.73 | 0.73 | 0.73 | 0.73 | 0.73 | 0.74 | — | — | — | — |
| initiator | APi-307 | — | — | — | — | — | — | — | — | 0.72 | 0.73 | 0.74 | 0.74 |
| Other | NPG | 0.10 | 0.10 | 0.10 | 0.10 | 0.10 | 0.10 | 0.10 | 0.10 | 0.10 | 0.10 | 0.10 | 0.10 |
| components | | | | | | | | | | | | | |
| Crosslinking | WT32-B75P | 12.50 | 12.50 | 12.50 | 12.50 | 12.50 | 12.50 | 12.50 | 12.50 | 12.50 | 12.50 | 12.50 | 12.50 |
| compound | Compound Q-1 | — | — | — | — | — | — | — | — | — | — | 2.97 | 2.97 |
| Other | Benzimidazole | 0.13 | 0.13 | 0.13 | 0.13 | 0.13 | 0.13 | 0.13 | 0.30 | — | — | — | — |
| components | Isonicotinamide | 0.52 | 0.52 | 0.52 | 0.52 | 0.52 | 0.52 | 0.52 | — | — | — | — | — |
| | XIRAN EF40 | 1.20 | 1.20 | 1.20 | 1.20 | 1.20 | 1.20 | 1.20 | — | 1.20 | 1.20 | 1.20 | 1.20 |
| | Amitrole | — | — | — | — | — | — | — | — | 1.13 | — | 1.13 | — |
| | 5-ATZ | — | — | — | — | — | — | — | — | — | 0.66 | — | 0.66 |
| Polymer | Type | X-1-3 | X-1-4 | X-1-2 | — | — | — | X-1-1 | X-1-1 | X-1-1 | X-1-1 | X-1-1 | X-1-1 |
| (X-1) | Amount | 0.24 | 0.24 | 0.24 | — | — | — | 0.05 | 0.04 | 0.05 | 0.05 | 0.05 | 0.05 |
| Polymer | Type | — | — | — | — | — | — | X-2-1 | X-2-1 | X-2-1 | X-2-1 | X-2-1 | X-2-1 |
| (X-2) | Amount | — | — | — | — | — | — | 0.19 | 0.18 | 0.19 | 0.19 | 0.19 | 0.19 |
| Other | Type | — | — | — | — | — | CX-1 | — | — | — | — | — | — |
| polymers | Amount | — | — | — | — | — | 0.24 | — | — | — | — | — | — |
| Amount ratio (X-1):(X-2) | | — | — | — | — | — | — | 20:80 | 18:82 | 20:80 | 20:80 | 20:80 | 20:80 |
| Fluorine- | F551A | — | — | — | 0.24 | — | — | — | — | — | — | — | — |
| based | | | | | | | | | | | | | |
| surfactant | | | | | | | | | | | | | |
| Evaluation | Thickness | C | C | B | C | C | E | A | A | A | A | A | A |
| | unevenness | | | | | | | | | | | | |
| | Bubble defects | A | A | C | D | A | A | A | A | A | A | A | A |
| | Adhesiveness | B | B | C | E | A | B | A | A | A | A | A | A |
| | Copper | B | B | C | E | E | E | A | A | A | A | A | A |
| | corrosion | | | | | | | | | | | | |

Abbreviations in Tables 6 to 8 are as follows.

Binder Polymer
Binder polymer A: alkali-soluble resin having following structure A (ratio of each constitutional unit=% by mass, Mw=18,000)
Binder polymer B: alkali-soluble resin having following structure B (ratio of each constitutional unit=% by mass, Mw=27,000)
Binder polymer C: alkali-soluble resin having following structure C (ratio of each constitutional unit=% by mass, Mw=18,000)

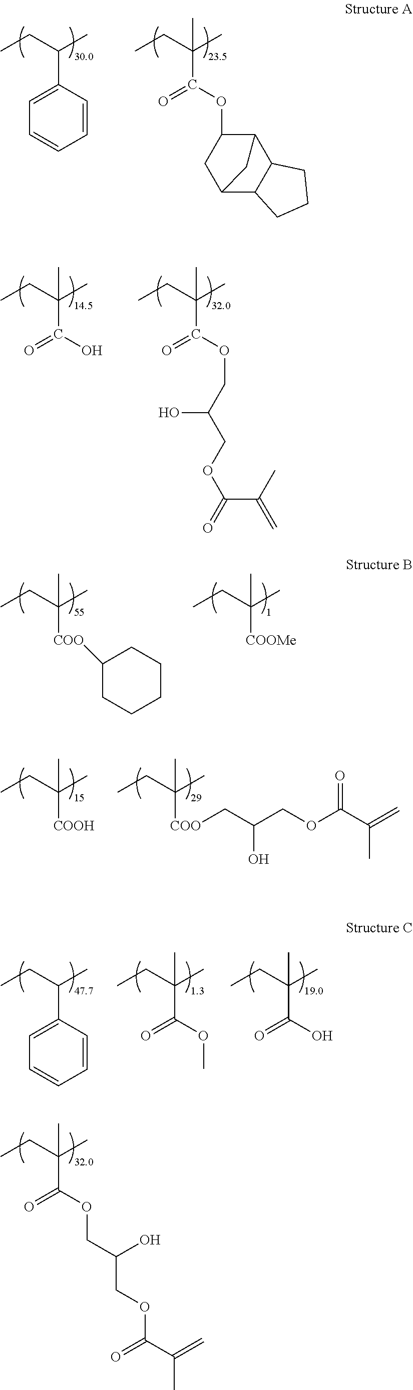

Polymerizable Compound
ADCP: NK ESTER A-DCP (Shin-Nakamura Chemical Co., Ltd., polymerizable compound)
TO2349: ARONIX TO-2349 (TOAGOSEI CO., LTD., polymerizable compound)
A-NOD-N: NK ESTER A-NOD-N(Shin-Nakamura Chemical Co., Ltd., polymerizable compound)
DPHA: KAYARAD DPHA (dipentaerythritol hexaacrylate, Nippon Kayaku Co., Ltd., polymerizable compound)
8UX-015A: Acrit 8UX-015A (urethane acrylate monomer, manufactured by Taisei Fine Chemical Co., Ltd.)

Photopolymerization Initiator
OXE-02: IRGACURE OXE02 (BASF SE, photopolymerization initiator)
Irg 907: Omnirad 907 (IGM Resins B.V., photopolymerization initiator)
APi-307: APi-307 (Shenzhen UV-ChemTech Co., Ltd., photopolymerization initiator)

Crosslinking Compound
WT32-B75P: DURANATE WT32-B75P (Asahi Kasei Corporation)

Compound Q-1: compound having the following structure

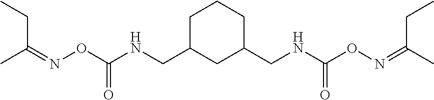 [SMILES: CC/C(C)=N\OC(=O)NCC1CCCC(CNC(=O)O/N=C(/C)CC)C1]

Other Components
NPG: N-phenylglycine
XIRAN EF40: XIRAN EF-40 (Polyscope Polymers BV)
Amitrole: 3-amino-1,2,4-triazole
5-amino-1H-tetrazole

Fluorine-Based Surfactant
F551A: (manufactured by DIC Corporation)

From the above results, it was found that, with the composition of the present example, a cured film with less thickness unevenness and less film defects was obtained.

In addition, it was found that, with the composition of the present example, a cured film having high adhesiveness to the substrate and excellent protective properties of the substrate was obtained.

### EXPLANATION OF REFERENCES

1: temporary support
3: photosensitive composition layer
5: refractive index adjusting layer
7: protective film

What is claimed is:

1. A composition comprising:
a binder polymer;
a polymerizable compound;
a polymer (X); and
a solvent,
wherein the polymer (X) includes a constitutional unit a represented by General Formula (A-1) or General Formula (A-2), and a constitutional unit β represented by General Formula (B), 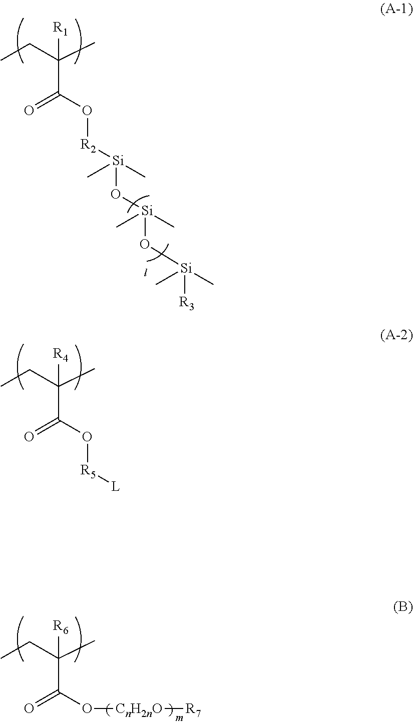
(in General Formula (A-1), R₁ represents a hydrogen atom or a methyl group, R₂ represents an alkylene group having 1 to 10 carbon atoms, R₃ represents an alkyl group having 1 to 4 carbon atoms, and l represents an integer of 5 to 100,
in General Formula (A-2), R₄ represents a hydrogen atom or a methyl group, R₅ represents an alkylene group having 1 to 10 carbon atoms, and L represents a trimethylsilyl group or a tris(trimethylsiloxy)silyl group,
in General Formula (B), R₆ represents a hydrogen atom or a methyl group, R₇ represents a hydrogen atom or an alkyl group having 1 to 18 carbon atoms, m represents an integer of 1 to 100, and n represents an integer of 1 to 4).

2. The composition according to claim 1,
wherein a mass ratio of the constitutional unit a and the constitutional unit β is 5:95 to 95:5.

3. The composition according to claim 1,
wherein the polymer (X) includes a polymer (X-1) including the constitutional unit represented by General Formula (A-1) and the constitutional unit represented by General Formula (B), and a polymer (X-2) including the constitutional unit represented by General Formula (A-2) and the constitutional unit represented by General Formula (B).

4. The composition according to claim 3,
wherein a mass ratio of the polymer (X-1) and the polymer (X-2) is 5:95 to 95:5.

5. The composition according to claim 4,
wherein the mass ratio of the polymer (X-1) and the polymer (X-2) is 10:90 to 50:50.

6. The composition according to claim 1,
wherein a content of the polymer (X) with respect to a total mass of the composition is more than 0.05% by mass and less than 1.5% by mass.

7. The composition according to claim 1,
wherein, in General Formula (A-1), l is an integer of 5 to 50.

8. A transfer film comprising, in the following order:
a temporary support; and
a photosensitive composition layer,
wherein the photosensitive composition layer is a layer formed of the composition according to claim 1.

9. A manufacturing method of a laminate, comprising:
bringing a surface of the transfer film according to claim 8 opposite to the temporary support into contact with a substrate having a conductive layer to bond the transfer film to the substrate, to obtain a photosensitive composition layer-attached substrate including the substrate, the conductive layer, the photosensitive composition layer, and the temporary support in this order;
exposing the photosensitive composition layer in a patterned manner; and
developing the exposed photosensitive composition layer to form a protective film pattern which protects the conductive layer,
wherein peeling off the temporary support from the photosensitive composition layer-attached substrate is provided between the bonding of the transfer film and the substrate and the exposing of the photosensitive composition layer or between the exposing of the photosensitive composition layer and the developing of the exposed photosensitive composition layer.

10. A cured film obtained by curing at least a part of the photosensitive composition layer in the transfer film according to claim 8.

11. A device comprising:
the cured film according to claim 10.
